(19) United States
(12) Patent Application Publication
(10) Pub. No.: US 2026/0060143 A1
(43) Pub. Date: Feb. 26, 2026

(54) SEMICONDUCTOR PACKAGE

(71) Applicant: Samsung Electronics Co., Ltd., Suwon-si (KR)

(72) Inventors: Junho Choi, Suwon-si (KR); Jiseok Hong, Suwon-si (KR); Dongwoo Kim, Suwon-si (KR); Hyunah Kim, Suwon-si (KR); Seyeong Seok, Suwon-si (KR); Seokhun Yun, Suwon-si (KR); Daseul Lee, Suwon-si (KR); Jonghyeon Chang, Suwon-si (KR); Younghwan Jin, Suwon-si (KR); Daeeun Heo, Suwon-si (KR)

(21) Appl. No.: 19/221,059

(22) Filed: May 28, 2025

(30) Foreign Application Priority Data
Aug. 21, 2024 (KR) 10-2024-0112339

(51) Int. Cl. H01L 25/16; H01L 23/00; H01L 23/31; H01L 23/48; H01L 23/522

(52) U.S. Cl. CPC H01L 25/16; H01L 23/3135; H01L 23/3171; H01L 23/481; H01L 23/5226; H01L 24/13; H01L 2224/13024; H01L 2225/06565

(57) ABSTRACT

Provided is a chip stack structure including a passivation layer, a plurality of conductive pillars passing through the passivation layer, a buffer chip located on the passivation layer, a plurality of core chips located on the buffer chip and stacked in a vertical direction, and a first molding layer located on the passivation layer and surrounding the buffer chip and the plurality of core chips, wherein an area of an upper surface of the passivation layer is greater than an area of a lower surface of the buffer chip.

### CROSS-REFERENCE TO RELATED APPLICATION

This application is based on and claims priority under 35 U.S. C. § 119 to Korean Patent Application No. 10-2024-0112339, filed on Aug. 21, 2024, in the Korean Intellectual Property Office, the disclosure of which is incorporated by reference herein in its entirety.

### BACKGROUND

The inventive concept relates to a semiconductor package, and more particularly, to a chip stack structure including a plurality of stacked core chips, and a semiconductor package including the same.

Recently, in accordance with the rapid development of the electronics industry and user demands, electronic devices have become more compact, multi-functional, and large-capacity, which requires highly integrated semiconductor chips. Accordingly, a semiconductor package is being designed that includes highly integrated semiconductor chips with an increased number of input/output (I/O) connection terminals while ensuring connection reliability.

### SUMMARY

The inventive concept provides a chip stack structure that simplifies the process and improves yield and a semiconductor package including the same.

In addition, the inventive concept is not limited to the mentioned above, and other inventive concepts not mentioned are clearly understood by those skilled in the art from the description below.

According to an aspect of the inventive concept, there is provided a chip stack structure including a passivation layer, a plurality of conductive pillars passing through the passivation layer, a buffer chip located on the passivation layer, a plurality of core chips located on the buffer chip and stacked in a vertical direction, and a first molding layer located on the passivation layer and surrounding the buffer chip and the plurality of core chips, wherein an area of an upper surface of the passivation layer is greater than an area of a lower surface of the buffer chip.

According to another aspect of the inventive concept, there is provided a chip stack structure including a passivation layer, a buffer chip located on the passivation layer and including a plurality of first lower pads, a plurality of core chips located on the buffer chip and stacked in a vertical direction, and a first molding layer located on an upper surface of the passivation layer and contacting side surfaces of the buffer chip and side surfaces of each of the plurality of core chips, wherein an area of the upper surface of the passivation layer is greater than an area of a lower surface of the buffer chip, an area of an upper surface of the buffer chip is greater than an area of a lower surface of each of the plurality of core chips, and side surfaces of the passivation layer are aligned with side surfaces of the first molding layer in the vertical direction.

According to another aspect of the inventive concept, there is provided a semiconductor package including a package substrate, a chip stack structure located on the package substrate, a semiconductor chip located on the package substrate and spaced apart from the chip stack structure in a horizontal direction, and a second molding layer located on the package substrate and surrounding the chip stack structure and the semiconductor chip, wherein the chip stack structure includes a passivation layer on the package substrate, a plurality of conductive pillars passing through the passivation layer and electrically connected to the package substrate, a buffer chip located on the passivation layer and electrically connected to the plurality of conductive pillars, a plurality of core chips located on the buffer chip and stacked in a vertical direction, and a first molding layer located on the passivation layer and surrounding the buffer chip and the plurality of core chips, wherein an area of an upper surface of the passivation layer is greater than an area of a lower surface of the buffer chip.

### BRIEF DESCRIPTION OF THE DRAWINGS

Embodiments will be more clearly understood from the following detailed description taken in conjunction with the accompanying drawings in which:

FIG. 1 is a schematic plan view of a chip stack structure according to an embodiment;

FIG. 2 is a schematic cross-sectional view of the chip stack structure of FIG. 1 taken along line A-A′ in FIG. 1;

FIG. 3 is a schematic cross-sectional view of a chip stack structure according to an embodiment;

FIG. 4 is a schematic plan view of a semiconductor package according to an embodiment;

FIG. 5 is a schematic cross-sectional view of the semiconductor package of FIG. 4 taken along line B-B′ in FIG. 4;

FIGS. 6A to 6I are diagrams illustrating a method of manufacturing a chip stack structure according to a process sequence, according to an embodiment; and

FIGS. 7A to 7J are diagrams illustrating a method of manufacturing a chip stack structure according to a process sequence, according to an embodiment.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise.

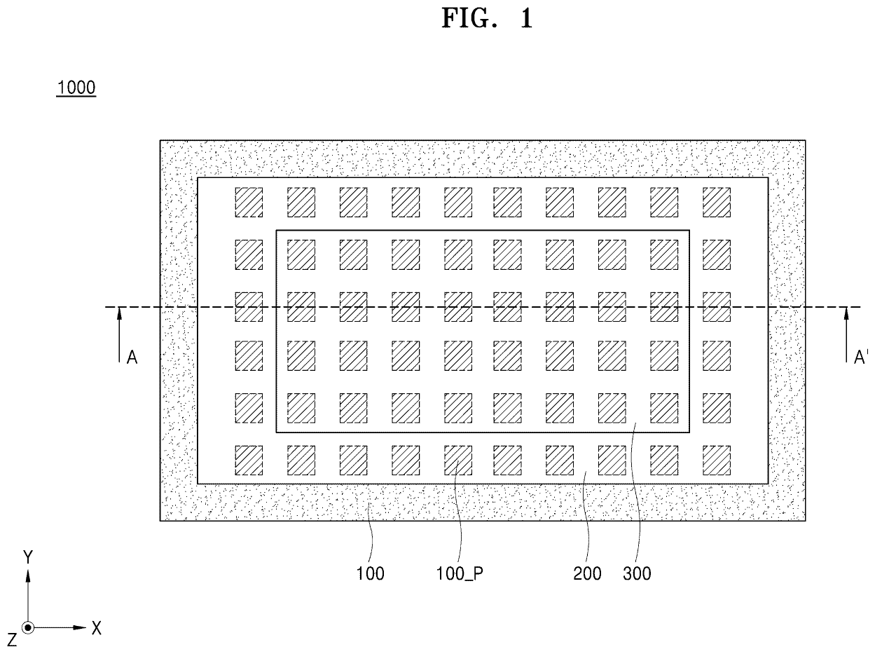

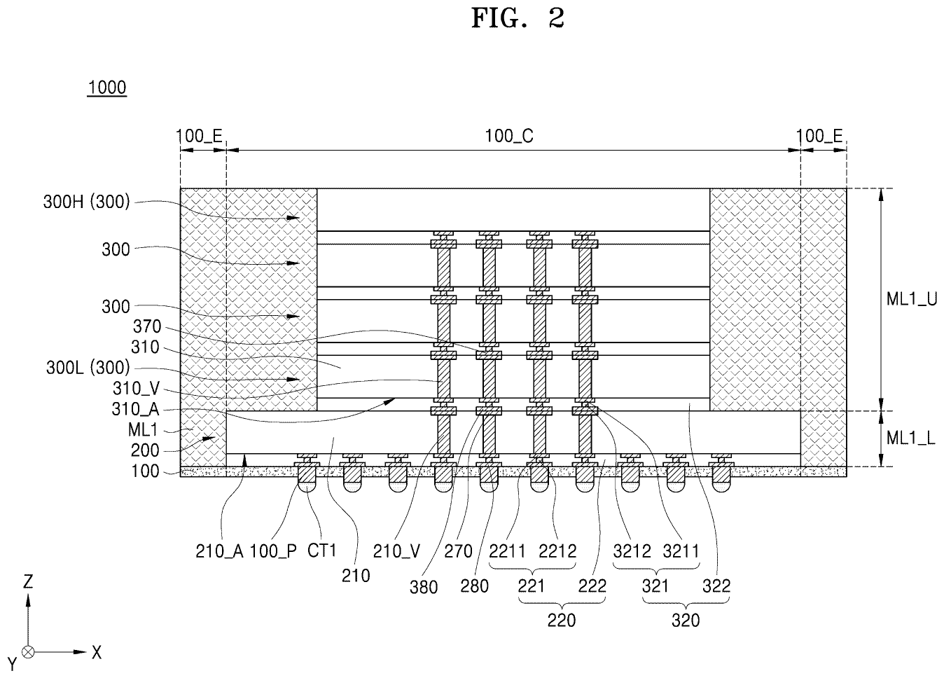

FIG. 1 is a schematic plan view of a chip stack structure 1000 according to an embodiment. FIG. 2 is a schematic cross-sectional view of the chip stack structure 1000 of FIG. 1 taken along line A-A′ in FIG. 1.

Referring to FIGS. 1 and 2, the chip stack structure 1000 may include a passivation layer 100, a plurality of conductive pillars 100_P, a buffer chip 200, a plurality of core chips 300, and a first molding layer ML1. Although the chip stack structure 1000 is shown to include four core chips 300 in FIG. 2, the inventive concept is not limited thereto. The chip stack structure 1000 may include two or more core chips 300. In some embodiments, the number of core chips 300 included in the chip stack structure 1000 may be a multiple of 4.

Hereinafter, unless otherwise specified, a direction parallel to an upper surface of the passivation layer 100 is defined as a first horizontal direction (X direction), a direction perpendicular to the upper surface of the passivation layer 100 is defined as a vertical direction (Z direction), and a direction perpendicular to each of the first horizontal direction (X direction) and the vertical direction (Z directions) is defined as a second horizontal direction (Y direction). A horizontal direction is defined as a direction combining the first horizontal direction (X direction) with the second horizontal direction (Y direction).

The plurality of conductive pillars 100_P may extend from the upper surface of the passivation layer 100 to a lower surface of the passivation layer 100. For example, the passivation layer 100 may protect a plurality of first lower pads 280 of the buffer chip 200, the plurality of conductive pillars 100_P may be respectively connected to the plurality of first lower pads 280 of the buffer chip 200, and external connection terminals CT1 may be respectively attached to the plurality of conductive pillars 100_P.

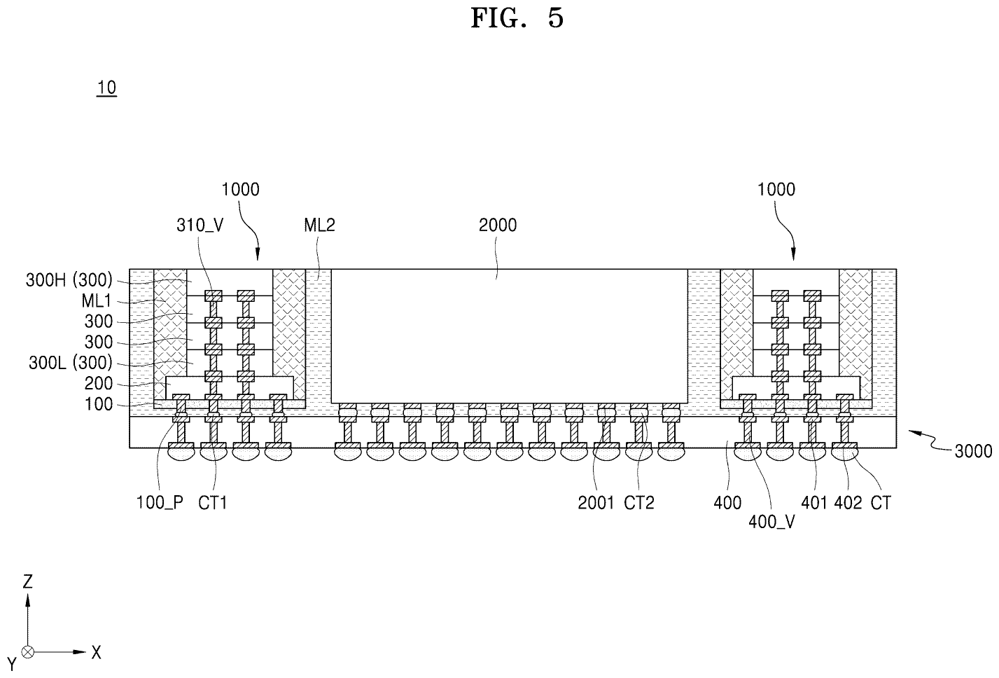

The external connection terminals CT1 may be configured to electrically and physically connect the chip stack structure 1000 to an external device on which the chip stack structure 1000 is mounted, for example, a package substrate 3000 (see FIG. 5). The external connection terminals CT1 may be formed, for example, from solder balls or solder bumps.

In some embodiments, an under bump metallization (UBM) layer may be positioned between the plurality of conductive pillars 100_P and the plurality of first lower pads 280 of the buffer chip 200 to facilitate adhesion between the plurality of conductive pillars 100_P and the plurality of first lower pads 280 of the buffer chip 200.

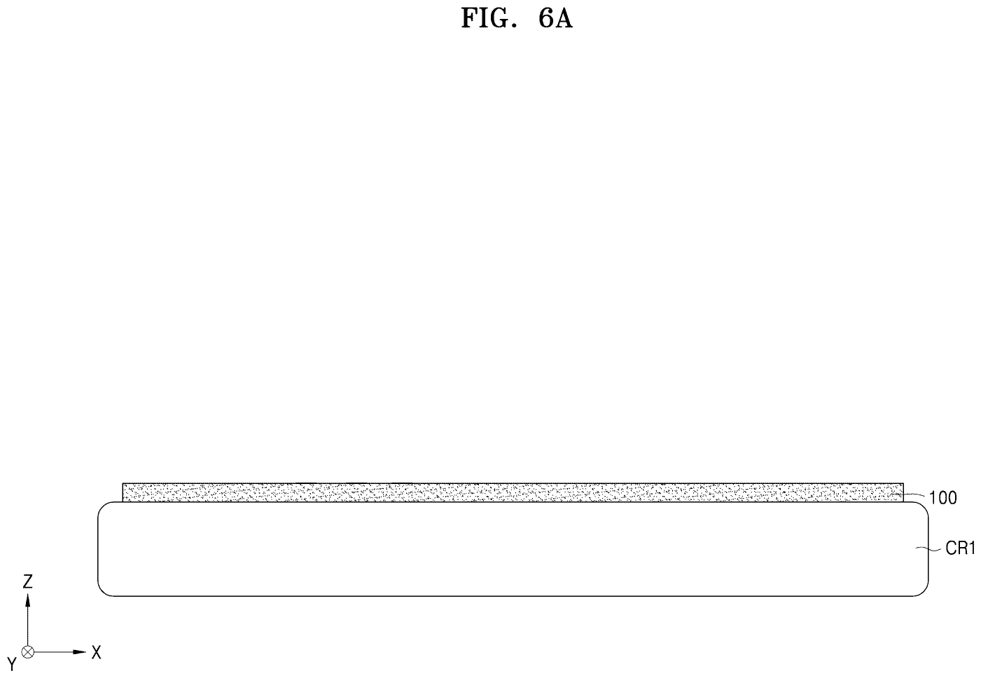

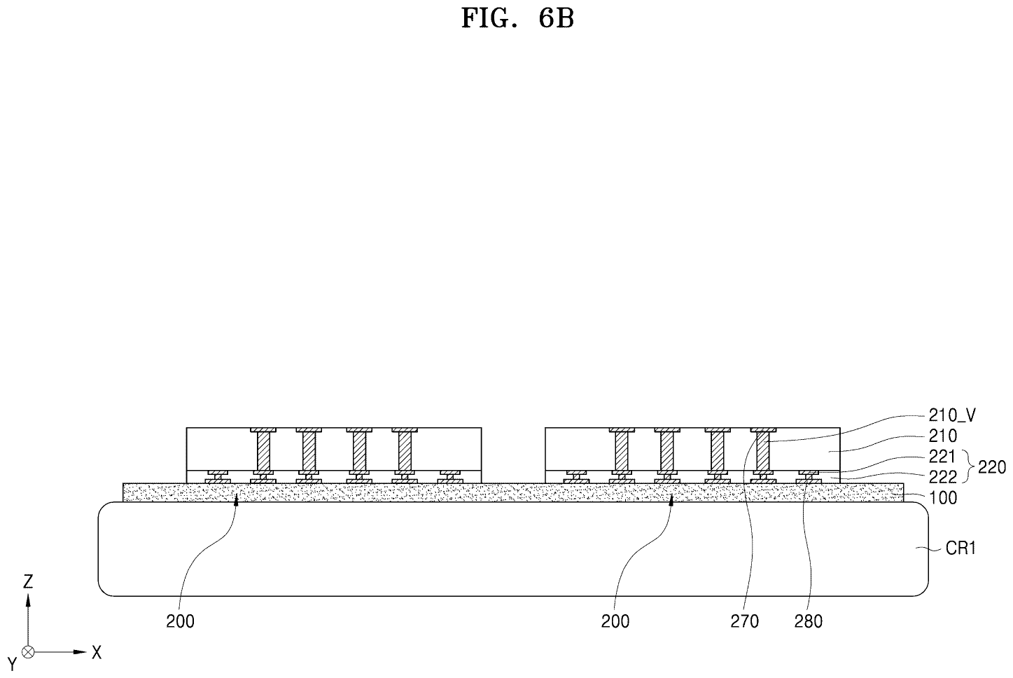

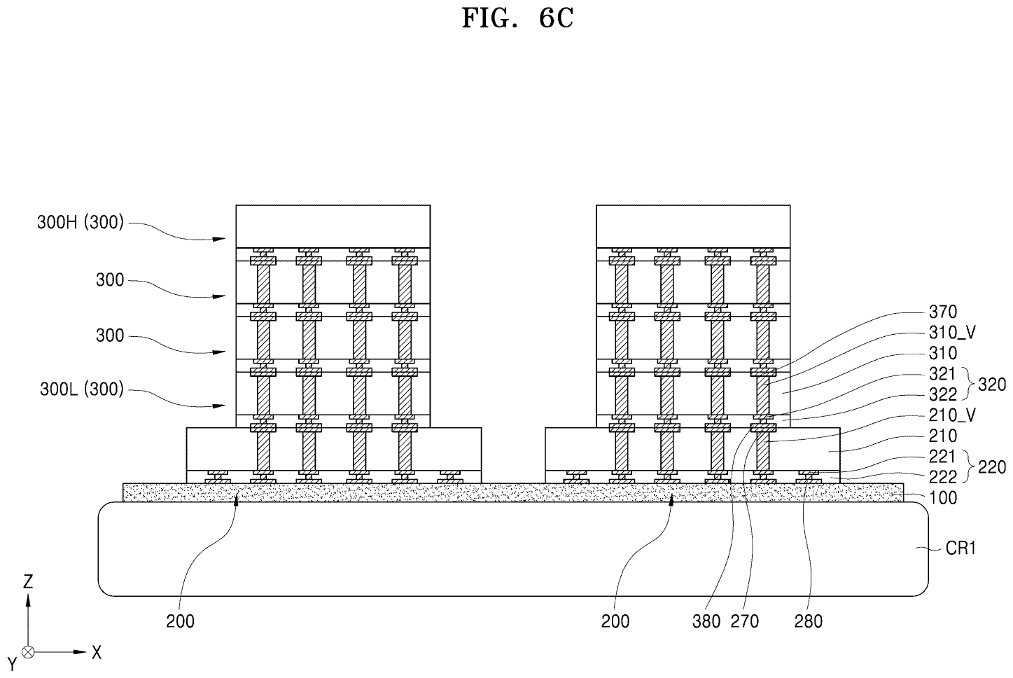

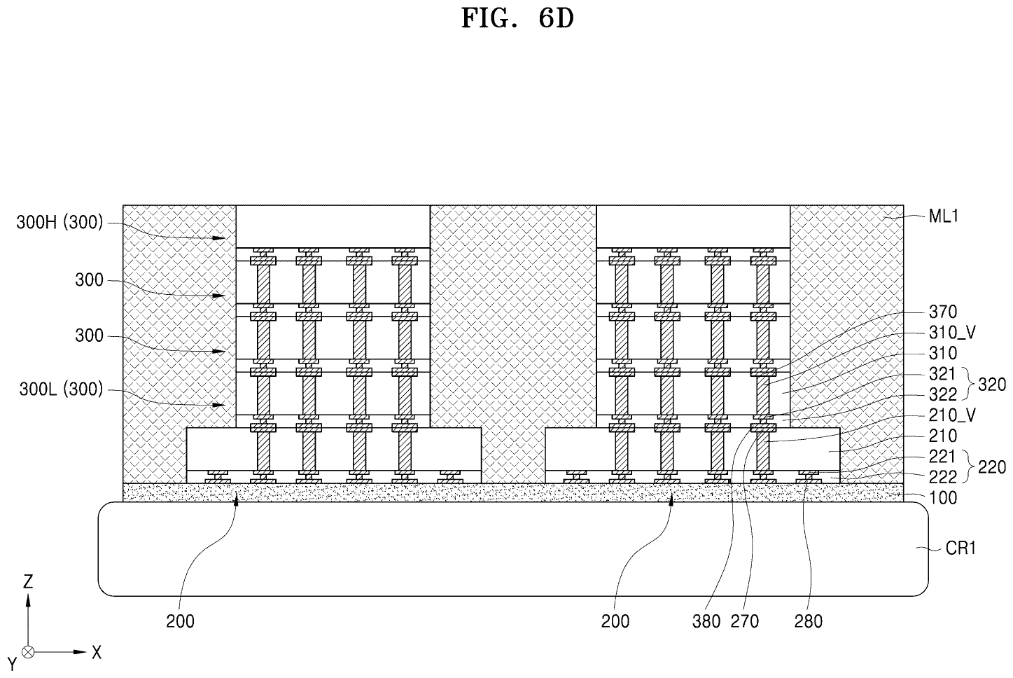

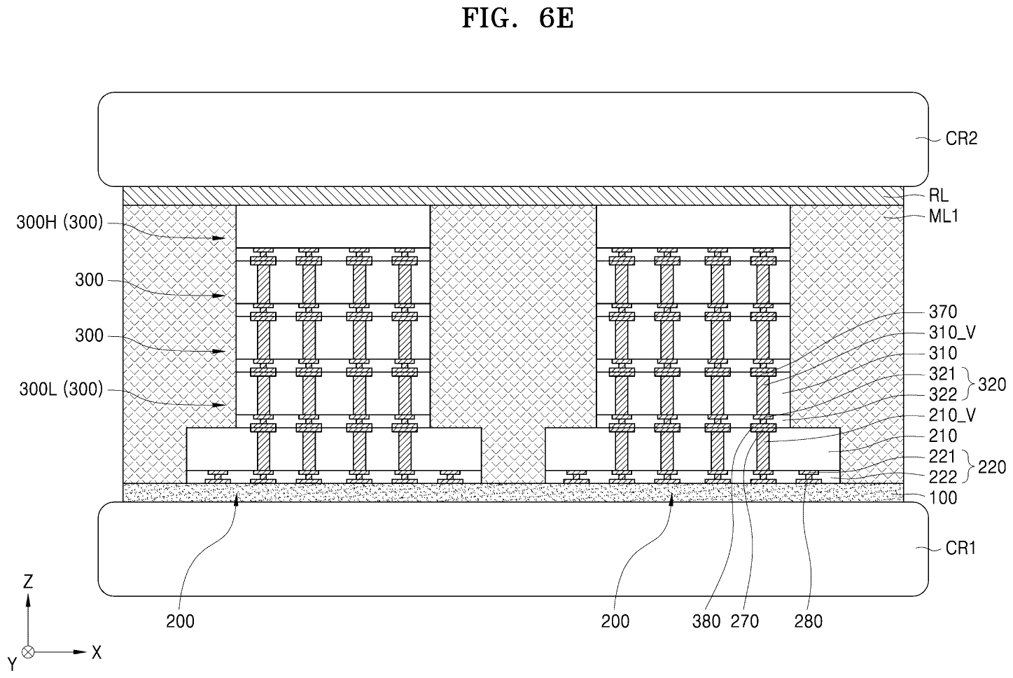

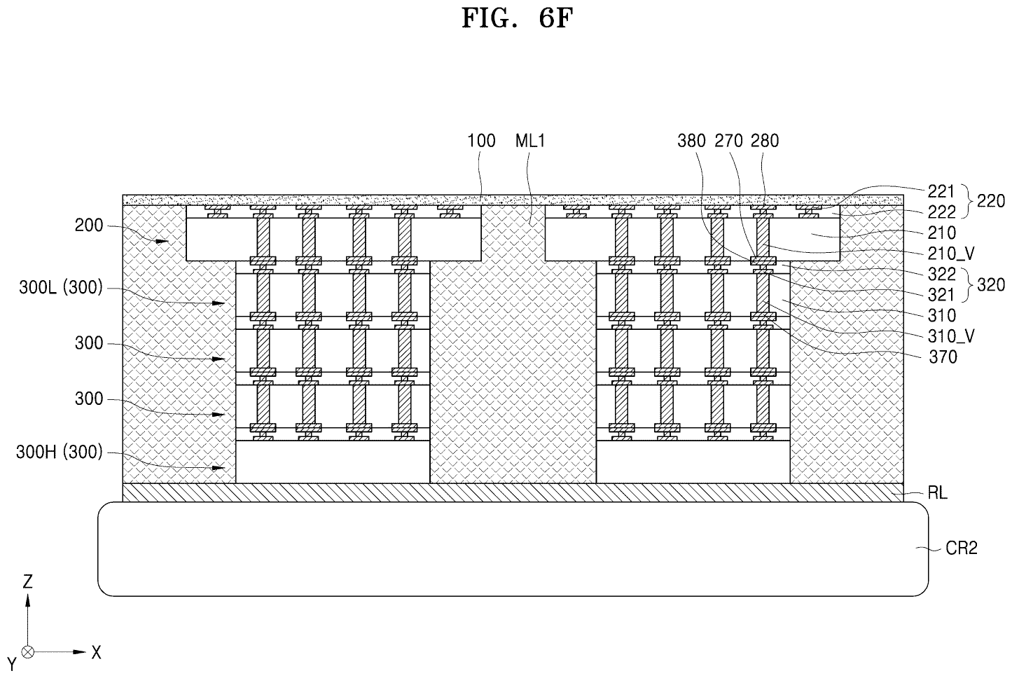

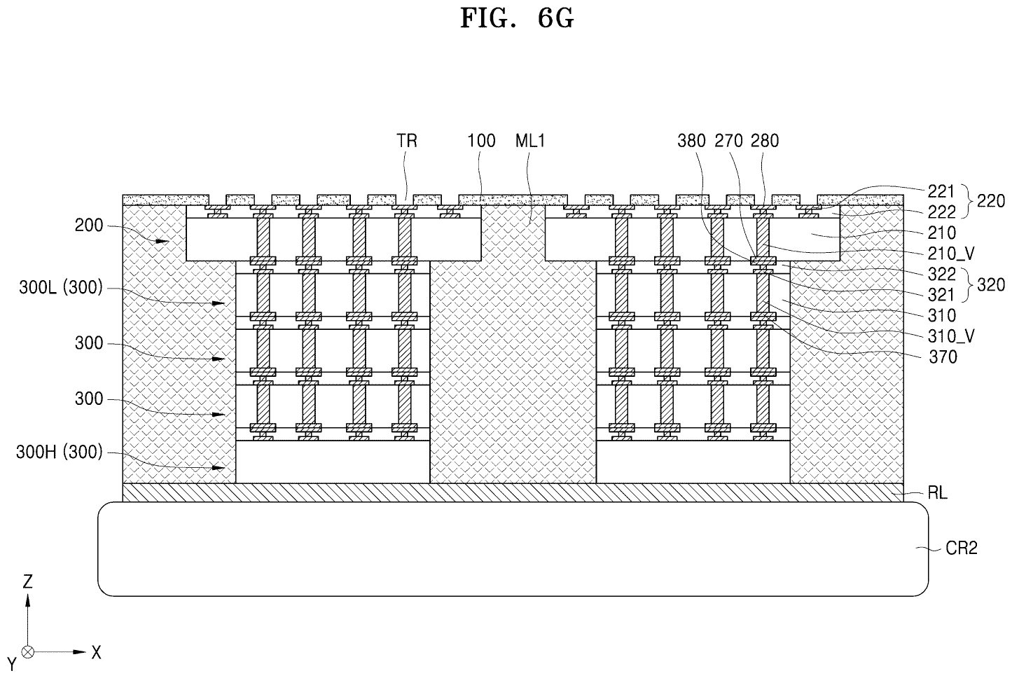

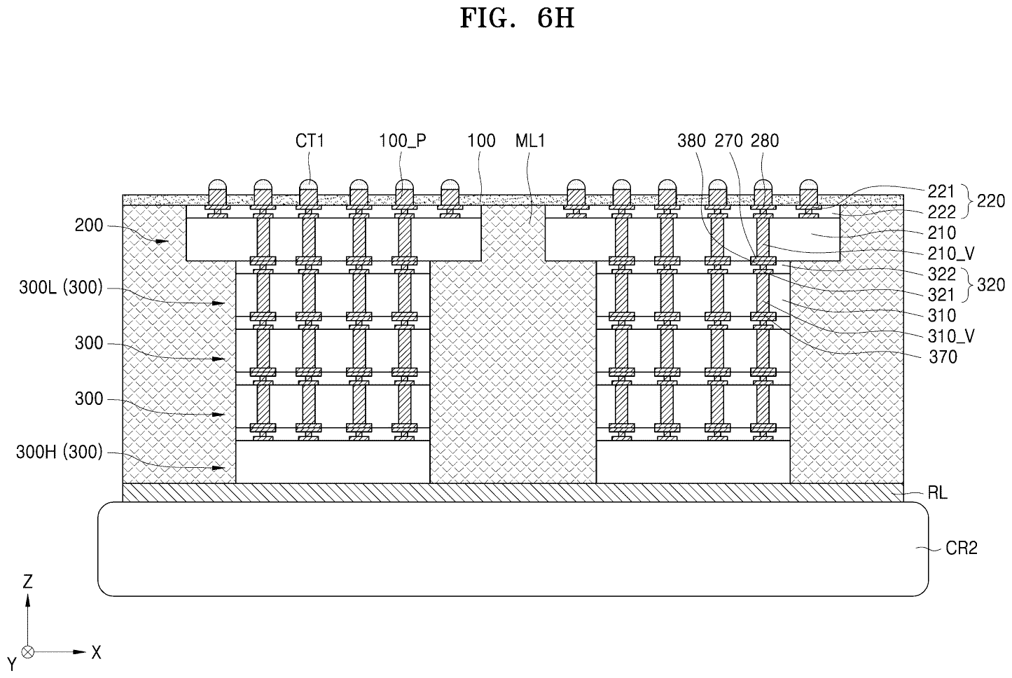

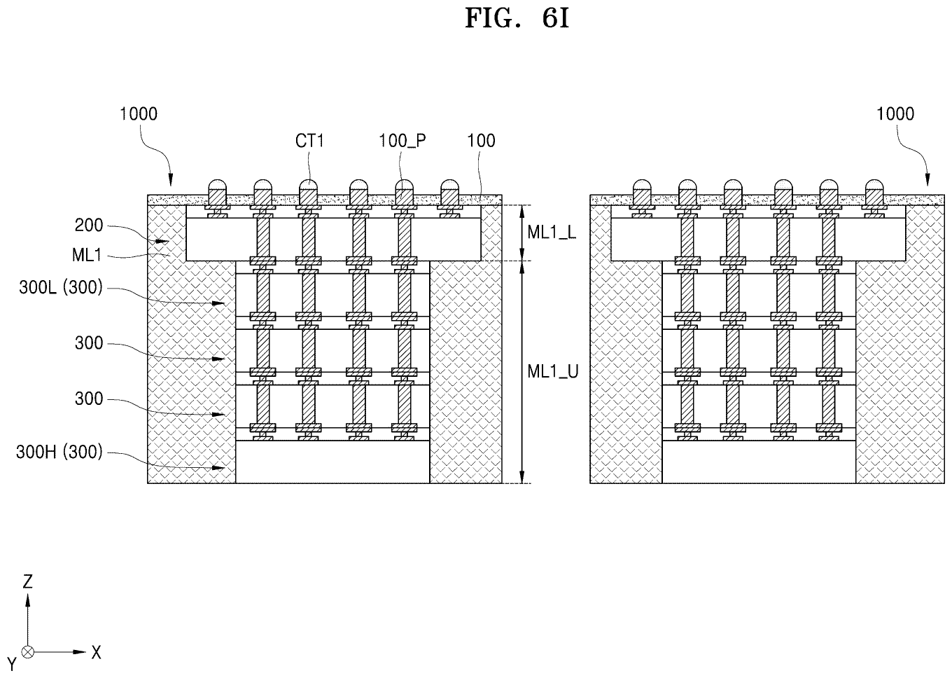

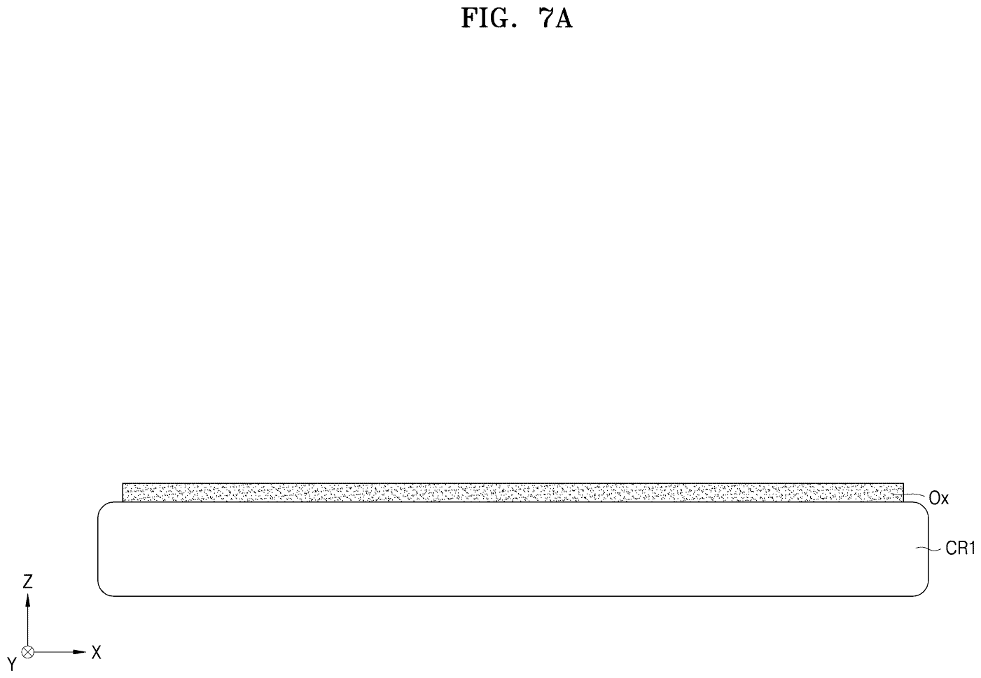

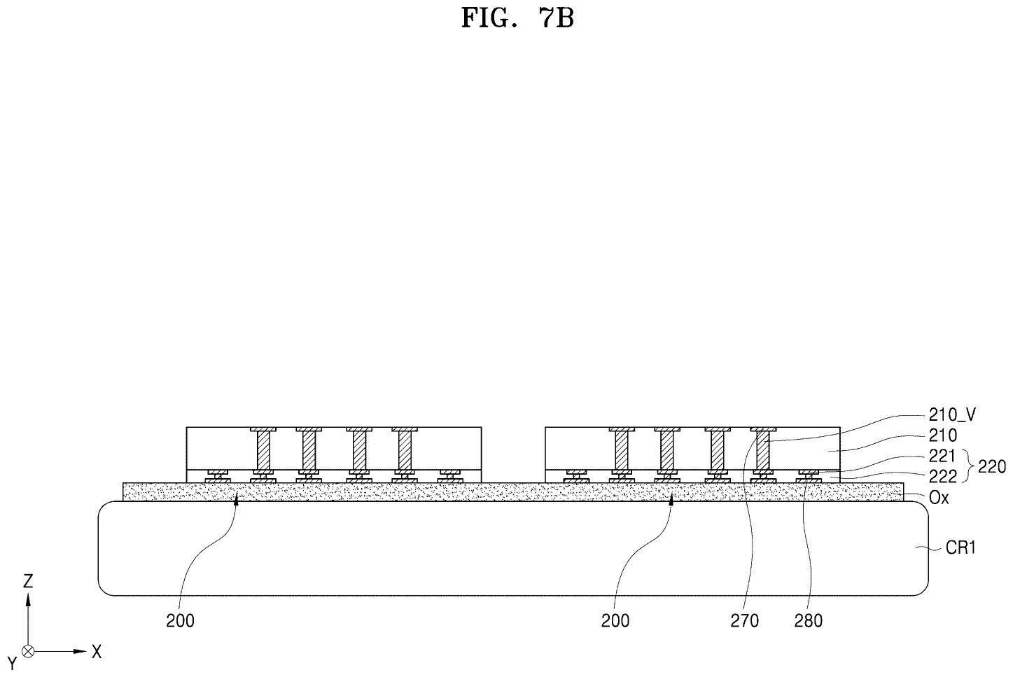

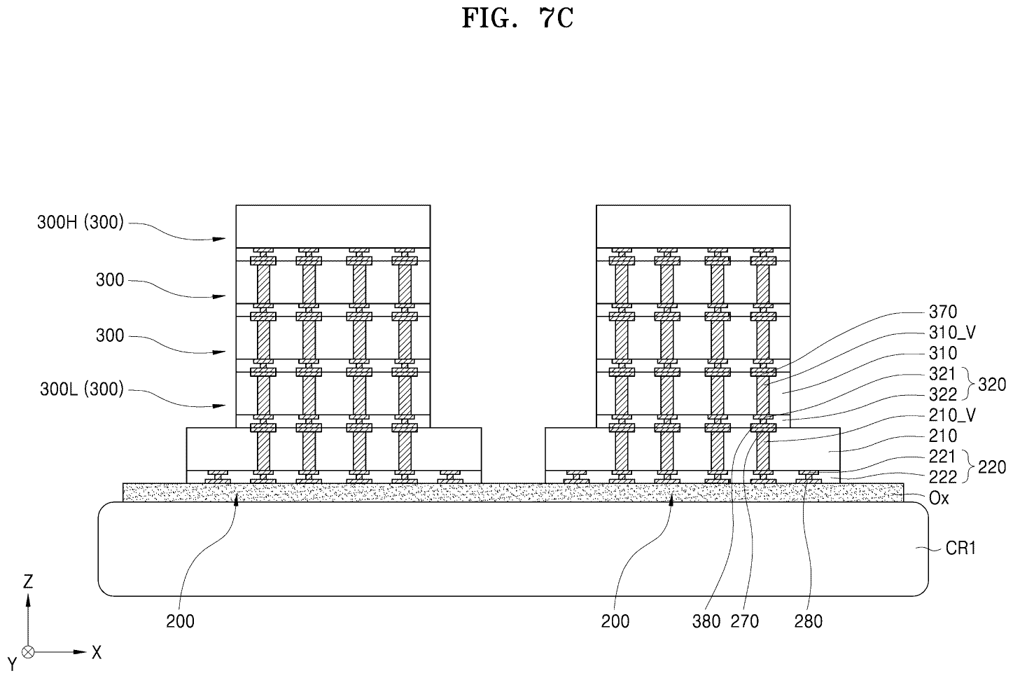

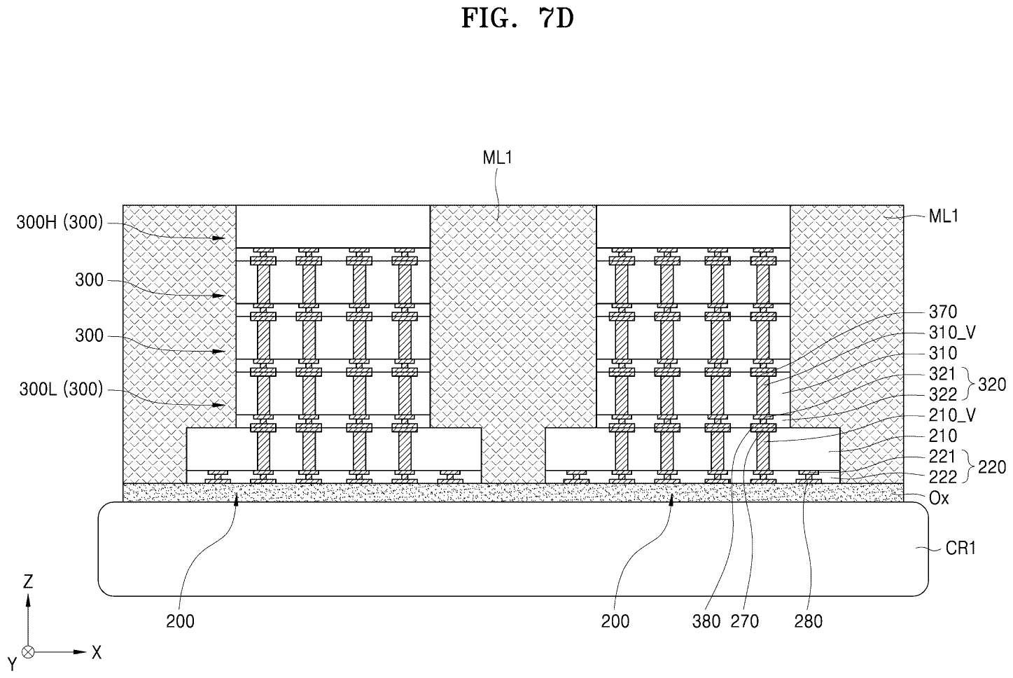

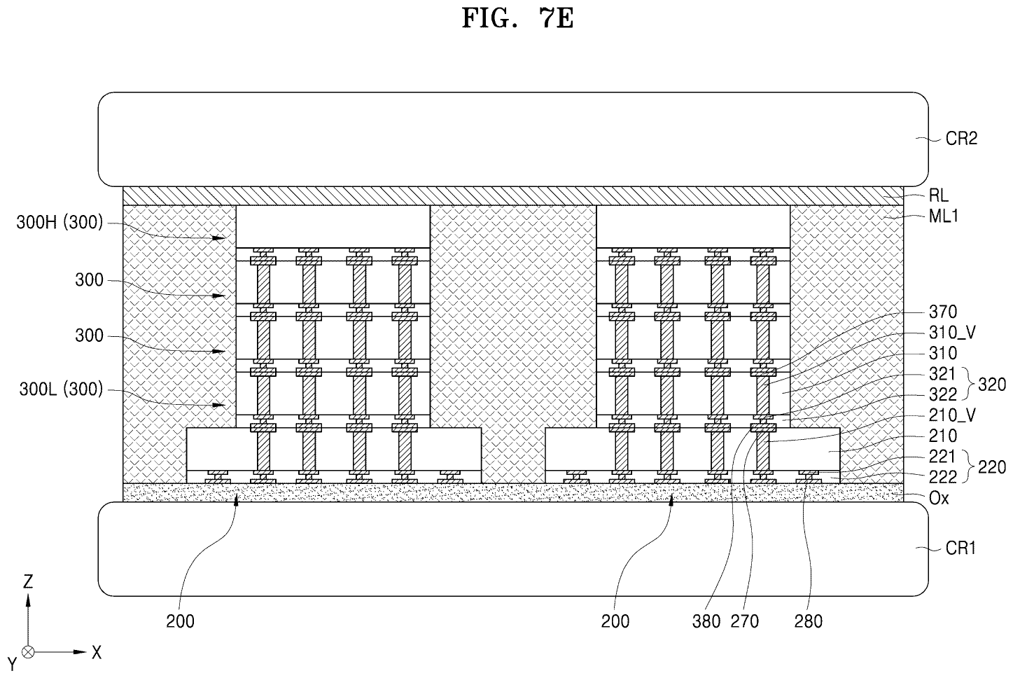

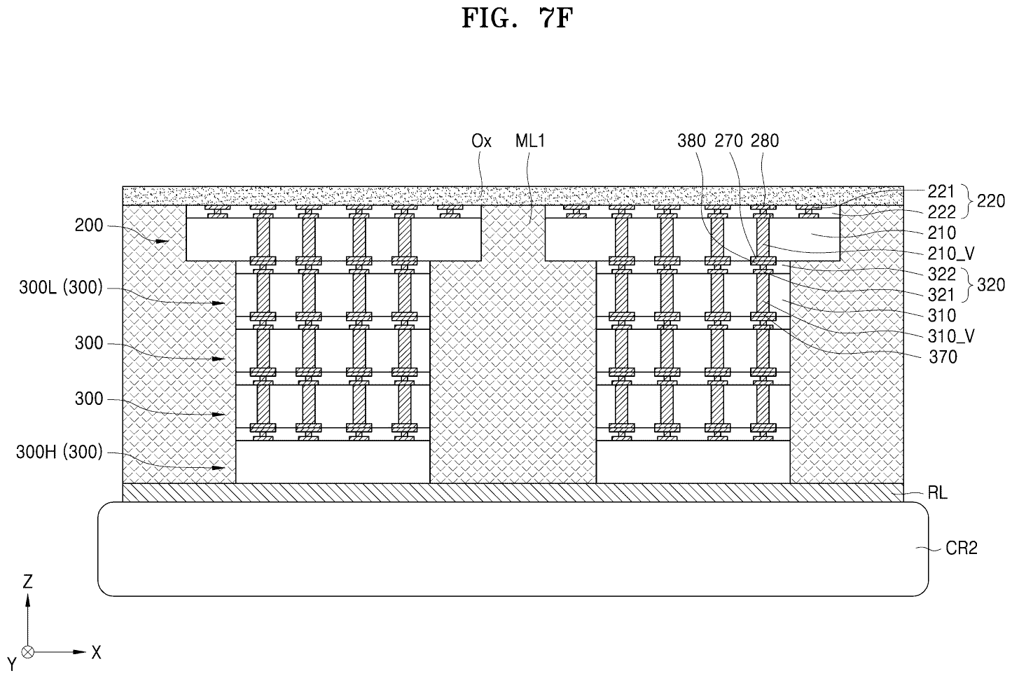

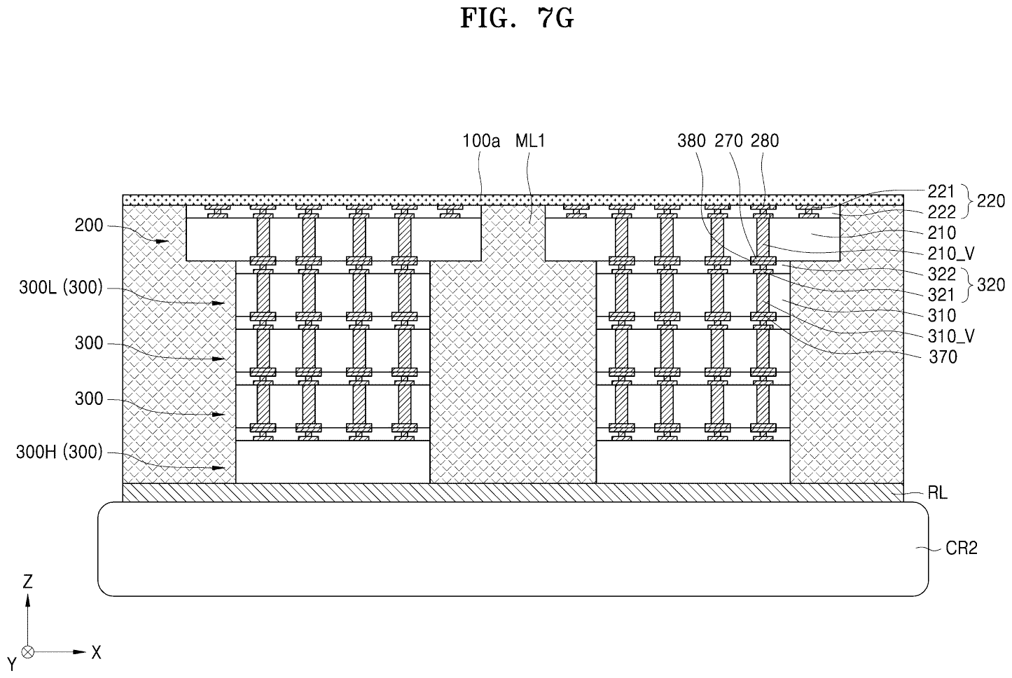

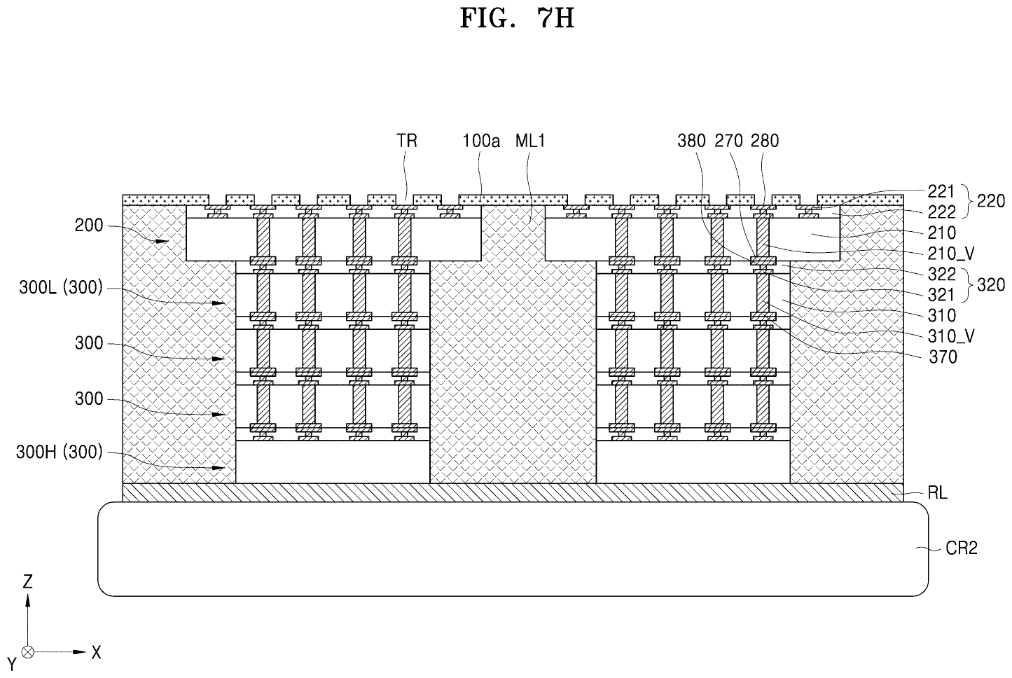

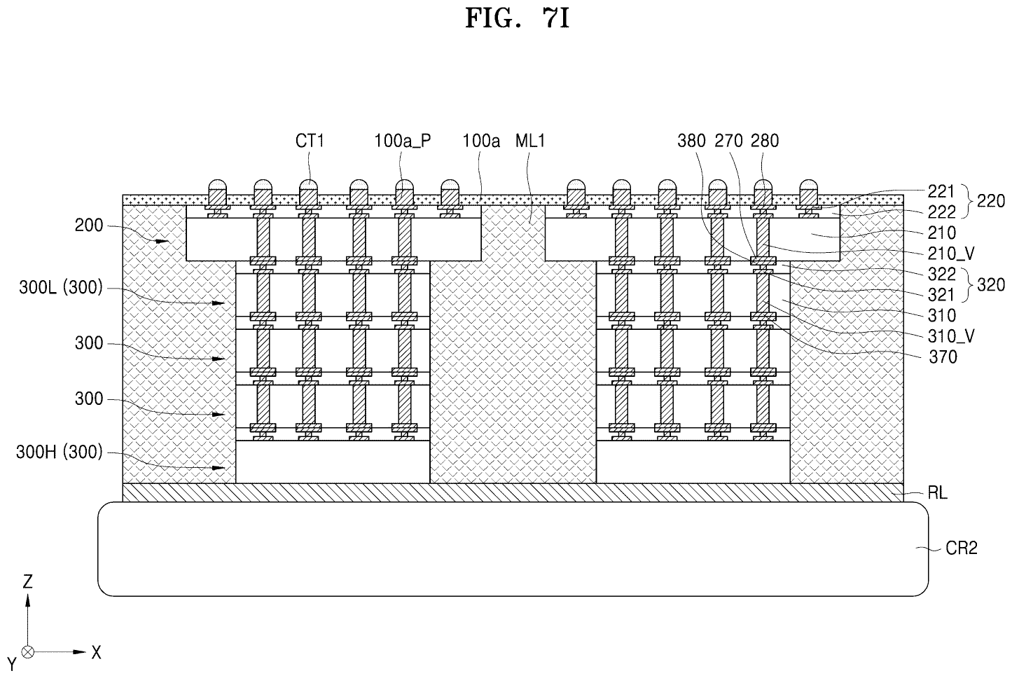

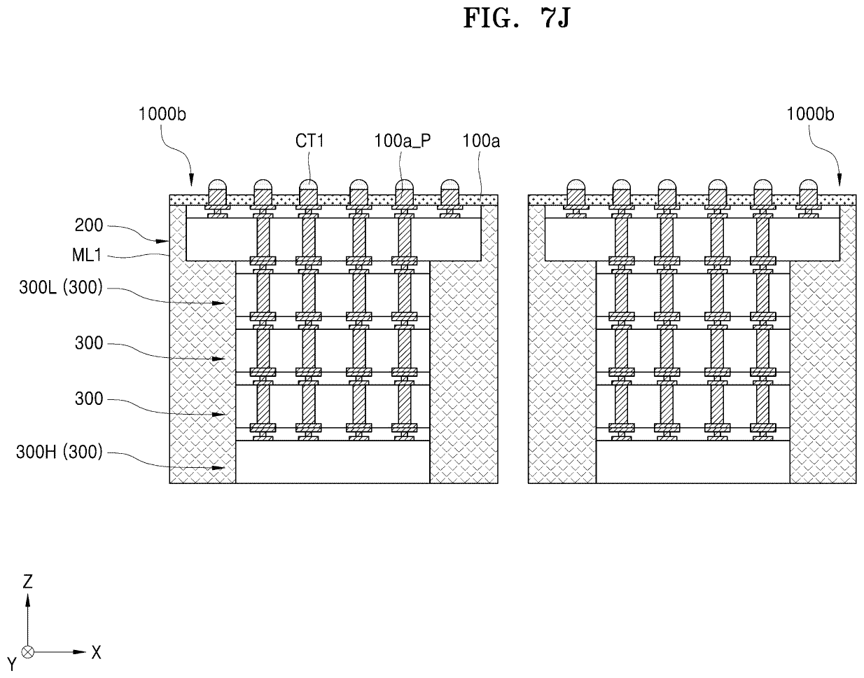

In some embodiments, the passivation layer 100 may include photosensitive polyimide (PSPI). In some embodiments, the passivation layer 100 may include an oxide, for example, silicon oxide. An embodiment in which the passivation layer 100 includes PSPI is described with reference to FIGS. 7A to 7J, and an embodiment in which the passivation layer 100 includes an oxide is described with reference to FIGS. 6A to 6I.

In some embodiments, the passivation layer 100 may have a single continuous homogenous layer structure (e.g., formed of the same base material throughout). For example, the layer may be formed with a single corresponding process (e.g., in situ-in a chamber without vacuum break to the chamber). For example, a patterned wiring structure may not be located within the passivation layer 100. In some embodiments, the thickness of the passivation layer 100 may be about 3μm to about 7μm (e.g., in the range of 3μm to 7μm).

In some embodiments, as the distance between each of the plurality of conductive pillars 100_P and the buffer chip 200 decreases, the horizontal width of each of the plurality of conductive pillars 100_P may decrease. For example, as the distance between each of the plurality of conductive pillars 100_P and the upper surface of the passivation layer 100 decreases, the horizontal width of each of the plurality of conductive pillars 100_P may decrease. For example, the plurality of conductive pillars 100_P may be referred to as a plurality of through vias. In some embodiments, the plurality of conductive pillars 100_P may include a metal material, such as aluminum, copper, or tungsten.

In some embodiments, each of the plurality of conductive pillars 100_P may protrude out of the passivation layer 100. For example, each of the plurality of conductive pillars 100_P may include a portion protruding downward from the lower surface of the passivation layer 100. For example, a lower surface of each of the plurality of conductive pillars 100_P may not be coplanar with the lower surface of the passivation layer 100.

The buffer chip 200 may be located on the passivation layer 100. The buffer chip 200 may be located directly on the passivation layer 100 with no intervening components. For example, side surfaces of the buffer chip 200 may overlap vertically with the upper surface of the passivation layer 100. For example, the side surfaces of the buffer chip 200 may be located above the upper surface of the passivation layer 100.

The buffer chip 200 may include a first substrate 210 having an active surface 210_A and an inactive surface on an opposite side of the first substrate 210, a first wiring structure 220 formed on the active surface 210_A of the first substrate 210, and a plurality of first through electrodes 210_V connected to the first wiring structure 220 and passing through at least a portion of the first substrate 210 of the buffer chip 200.

The first substrate 210 may include, for example, a semiconductor material, such as silicon (Si). Alternatively, the first substrate 210 may include a semiconductor material, such as germanium (Ge).

A semiconductor device including various types of individual devices may be formed on the active surface 210_A of the first substrate 210. The individual devices of the buffer chip 200 may include various microelectronic devices, for example, a metal-oxide-semiconductor field effect transistor (MOSFET), such as a complementary metal-oxide-semiconductor (CMOS) transistor, an active device, a passive device, and the like.

The first wiring structure 220 may include a first wiring pattern 221 and a first wiring insulating layer 222 surrounding the first wiring pattern 221. The first wiring pattern 221 may include a first wiring line 2211 extending in the horizontal direction and a first wiring via 2212 extending from the first wiring line 2211 in the vertical direction (Z direction). The first wiring pattern 221 may be electrically connected to the individual devices of the buffer chip 200.

The buffer chip 200 may be arranged such that the active surface 210_A of the first substrate 210 faces downward in the vertical direction (Z direction) and the inactive surface thereof faces upward in the vertical direction (Z direction). For example, the buffer chip 200 may be located on the passivation layer 100 such that the active surface 210_A of the first substrate 210 faces the passivation layer 100. Unless otherwise stated herein, an upper surface of the buffer chip 200 refers to a side that the inactive surface of the first substrate 210 faces (e.g., the side with a normal direction aligned with the normal direction of the inactive surface of the first substrate 210) and a lower surface of the buffer chip 200 refers to a side that the active surface 210_A of the first substrate 210 faces (e.g., the side with a normal direction aligned with the normal direction of the active surface 210_A of the first substrate 210).

In some embodiments, the area of the lower surface of the buffer chip 200 may be less than the area of the upper surface of the passivation layer 100. For example, the width of the buffer chip 200, (e.g., the linear extent thereof in the horizontal direction), may be less than the width of the passivation layer 100. The side surfaces of the buffer chip 200 may overlap with the upper surface of the passivation layer 100 in the vertical direction (Z direction).

In some embodiments, the passivation layer 100 may be in contact with the first wiring insulating layer 222 of the first wiring structure 220 of the buffer chip 200. For example, the first wiring insulating layer 222 of the first wiring structure 220 of the buffer chip 200 may be covalently bonded to the passivation layer 100 by heat and form one body with the passivation layer 100. For example, each of the first wiring insulating layer 222 and the passivation layer 100 may include silicon oxide.

The buffer chip 200 may include the plurality of first lower pads 280 and a plurality of first upper pads 270. The plurality of first lower pads 280 may be located on the lower surface of the buffer chip 200 and the plurality of first upper pads 270 may be located on the upper surface of the buffer chip 200. The plurality of first lower pads 280 may be part of the first wiring structure 220. For example, the plurality of first lower pads 280 may be part of the first wiring pattern 221 of the first wiring structure 220. The plurality of first upper pads 270 may be electrically and respectively connected to the plurality of first lower pads 280 through the plurality of first through electrodes 210_V. In some embodiments, each upper pad 270 of the plurality of first upper pads 270 may form one body with a respective first through electrode 210_V of the plurality of first through electrodes 210_V.

In some embodiments, the passivation layer 100 may be divided into a center region 100_C and an edge region 100_E. For example, the edge region 100_E of the passivation layer 100 may surround the center region 100_C of the passivation layer 100. In the center region 100_C of the passivation layer 100, the upper surface of the passivation layer 100 may be in contact with the buffer chip 200. In the edge region 100_E of the passivation layer 100, the upper surface of the passivation layer 100 may be in contact with the first molding layer ML1. For example, the area of the upper surface of the passivation layer 100 in the center region 100_C of the passivation layer 100 may be the same as the area of the lower surface of the buffer chip 200.

In some embodiments, the plurality of conductive pillars 100_P may be located within the center region 100_C of the passivation layer 100. For example, the plurality of conductive pillars 100_P may not be located within the edge region 100_E of the passivation layer 100. The plurality of conductive pillars 100_P is located under the buffer chip 200 and may be electrically connected to the buffer chip 200.

For example, the plurality of conductive pillars 100_P may be in contact with the plurality of first lower pads 280 of the buffer chip 200. Each of the plurality of conductive pillars 100_P may be located on a lower surface of a respective first lower pad 280 of the plurality of first lower pads 280. For example, the plurality of conductive pillars 100_P may overlap with the plurality of first lower pads 280 of the buffer chip 200, respectively, in the vertical direction (Z direction). For example, the external connection terminals CT1 respectively attached to the plurality of conductive pillars 100_P may also be located below the buffer chip 200.

The plurality of core chips 300 may be located on the buffer chip 200. The plurality of core chips 300 may be stacked in the vertical direction (Z direction). Each of the plurality of core chips 300 may include a second substrate 310 having an active surface 310_A and an inactive surface on an opposite side of the second substrate 310, and a second wiring structure 320 formed on the active surface 310_A of the second substrate 310.

Each of the plurality of core chips 300, other than a top core chip 300H (e.g., the uppermost core chip 300H), may further include a plurality of second through electrodes 310_V connected to the second wiring structure 320 and passing through at least a portion of the second substrate 310. The top core chip 300H located at the top of the plurality of core chips 300 may not include the plurality of second through electrodes 310_V. However, the inventive concept is not limited thereto. The top core chip 300H may also include the plurality of second through electrodes 310_V.

The second substrate 310 may include, for example, a semiconductor material, such as Si. Alternatively, the second substrate 310 may include a different semiconductor material, such as Ge.

A semiconductor device including various types of individual devices may be formed on the active surface 310_A of the second substrate 310. The individual devices of each of the plurality of core chips 300 may include a memory cell. For example, the memory cell may include a non-volatile memory cell, such as flash memory, phase-change random-access memory (PRAM), magnetoresistive random-access memory (MRAM), ferroelectric random-access memory (FeRAM), or resistive random-access memory (RRAM). In some embodiments, the memory cell may include a volatile memory cell, such as dynamic random-access memory (DRAM) or static random-access memory (SRAM).

The second wiring structure 320 may include a second wiring pattern 321 and a second wiring insulating layer 322 surrounding the second wiring pattern 321. The second wiring pattern 321 may include a second wiring line 3211 extending in the horizontal direction and a second wiring via 3212 extending from the second wiring line 3211 in the vertical direction (Z direction). The second wiring structure 320 of each of the plurality of core chips 300 may be electrically connected to the individual devices of a corresponding core chip 300 of the plurality of core chips 300.

Each of the plurality of core chips 300 may be sequentially stacked on the buffer chip 200 in the vertical direction (Z direction) such that the active surface 310_A of the second substrate 310 faces downward in the vertical direction (z direction). For example, each of the plurality of core chips 300 may be stacked on the buffer chip 200 such that the active surface 310_A of the second substrate 310 faces the buffer chip 200. Unless otherwise stated herein, the upper surface of each of the plurality of core chips 300 refers to a side that the inactive surface of the second substrate 310 faces (e.g., the normal direction of the upper surface is aligned with the normal direction of the inactive surface of the second substrate 310) and the lower surface of each of the plurality of core chips 300 refers to a side that the active surface 310_A of the second substrate 310 faces (e.g., the normal direction of the lower surface is aligned with the normal direction of the active surface 310_A of the second substrate 310).

Each of the plurality of core chips 300 may include a plurality of second lower pads 380 and a plurality of second upper pads 370. The plurality of second lower pads 380 of a core chip 300 may be located on the lower surface of the core chip 300 and may be part of the second wiring structure 320 of the core chip 300. The plurality of second upper pads 370 of a core chip 300 may be located on the upper surface of the core chip 300 and may be electrically connected to the plurality of second lower pads 380 through the plurality of second through electrodes 310_V. In some embodiments, a second upper pad 370 may form one body with a respective second through electrodes 310_V. In some embodiments, the top core chip 300H may not include the plurality of second through electrodes 310_V and the plurality of second upper pads 370.

In some embodiments, the thickness of each of the plurality of core chips 300, such as the linear extent thereof in the vertical direction (Z direction), may be about 20μm to about 80μm. The thickness of each of the plurality of core chips 300 may have generally the same value.

In some embodiments, the widths of the plurality of core chips 300, e.g., the lengths thereof in the horizontal direction, may be substantially the same. The side surfaces of the plurality of core chips 300 may be aligned with each other in the vertical direction (Z direction).

In some embodiments, the area of the lower surface of each of the plurality of core chips 300 may be less than the area of the upper surface of the buffer chip 200. For example, the width of each of the plurality of core chips 300 may be less than the width of the buffer chip 200. For example, the side surfaces of the plurality of core chips 300 may overlap with the upper surface of the buffer chip 200 in the vertical direction (Z direction).

In some embodiments, the buffer chip 200 may include a serial-parallel conversion circuit and a controller for controlling the plurality of core chips 300, wherein each of the plurality of core chips 300 may include a memory chip including memory cells. For example, the chip stack structure 1000 including the buffer chip 200 and the plurality of core chips 300 may constitute a high bandwidth memory (HBM). The buffer chip 200 may be referred to as an HBM controller die, and each of the plurality of core chips 300 may be referred to as a DRAM die. The HBM controller die may include circuitry for managing the flow of data to the core chips 300.

In some embodiments, a bottom core chip 300L located at the bottom of the plurality of core chips 300 may be bonded to the buffer chip 200 through hybrid bonding. For example, the plurality of second lower pads 380 of the bottom core chip 300L and the plurality of first upper pads 270 of the buffer chip 200 may be diffusion bonded by heat such that corresponding second lower pads 380 and first upper pads 270 form one body.

For example, in the process of diffusion bonding between the plurality of second lower pads 380 of the bottom core chip 300L and the plurality of first upper pads 270 of the buffer chip 200, the second wiring insulating layer 322 surrounding the plurality of second lower pads 380 of the bottom core chip 300L may be diffusion bonded with an insulating layer surrounding the plurality of first upper pads 270 of the buffer chip 200 to form one body. In some embodiments, the area of the upper surface of the insulating layer surrounding the plurality of first upper pads 270 of the buffer chip 200 is the same as the area of the upper surface of the buffer chip 200 and part of the upper surface of the insulating layer surrounding the plurality of first lower pads 270 of the buffer chip 200 may be in contact with the first molding layer ML1.

In some embodiments, adjacent core chips 300 among the plurality of core chips 300 may be bonded to each other through hybrid bonding. For convenience of explanation, two adjacent core chips 300 may be described herein. The plurality of second upper pads 370 of the lower core chip 300 among the two core chips 300 and the plurality of second lower pads 380 of the upper core chip 300 among the two core chips 300 may be diffusion bonded by heat to form one body between respective second upper pads 370 and second lower pads 380. Additionally, the insulating layer surrounding the plurality of second upper pads 370 of the lower core chip 300 and the insulating layer surrounding the plurality of second lower pads 380 of the upper core chip 300 may also be diffusion bonded by heat to form one body.

However, a method of bonding the bottom core chip 300L to the buffer chip 200 and a method of bonding the plurality of core chips 300 to each other are not limited thereto. The bottom core chip 300L and the buffer chip 200 may be bonded to the plurality of core chips 300 by an adhesive film, such as an anisotropic conductive film (ACF), or a direct bonding method.

The first molding layer ML1 may be located on the passivation layer 100. The first molding layer ML1 may surround the buffer chip 200 and the plurality of core chips 300. For example, the first molding layer ML1 may be in contact with the upper surface of the passivation layer 100 and may be in contact with the side surfaces of the buffer chip 200 and the side surfaces of the plurality of core chips 300. For example, the upper surface of the first molding layer ML1 may be coplanar with the upper surface of the top core chip 300H.

The side surfaces of the first molding layer ML1 may be aligned with the side surfaces of the passivation layer 100 in the vertical direction (Z direction). For example, one side surface of the passivation layer 100 and one side surface of the first molding layer ML1, which are aligned with each other, may be coplanar.

In some embodiments, the first molding layer ML1 may be divided into an upper region ML1_U and a lower region ML1_L. The upper region ML1_U of the first molding layer ML1 and the lower region ML1_L of the first molding layer ML1 may be formed in one process and there may be no interface (e.g., a change in structure or a discontinuity) between the upper region ML1_U of the first molding layer ML1 and the lower region ML1_L of the first molding layer ML1.

The lower region ML1_L of the first molding layer ML1 may include a portion of the first molding layer ML1 in contact with the upper surface of the passivation layer 100 and in contact with the side surface of the buffer chip 200. The upper region ML1_U of the first molding layer ML1 may be located above the lower region ML1_L of the first molding layer ML1 and may include a portion of the first molding layer ML1 in contact with the upper surface of the buffer chip 200 and in contact with the side surface of the plurality of core chips 300.

In the lower region ML1_L of the first molding layer ML1, the length between a side surface of the first molding layer ML1 exposed to the outside and a side surface of the first molding layer ML1 in contact with the buffer chip 200, among the side surfaces of the first molding layer ML1, may have a first width. For example, the first width may be a distance between an outer surface and an inner surface of the first molding layer ML1, in the lower region ML1_L of the first molding layer ML1.

In the upper region ML1_U of the first molding layer ML1, the distance between a side surface of the first molding layer ML1 exposed to the outside and a side surface of the first molding layer ML1 in contact with the plurality of core chips 300, among the side surfaces of the first molding layer ML1, may be a second width. For example, the second width may be a distance between an outer surface and an inner surface of the first molding layer ML1, in the upper region ML1_U of the first molding layer ML1.

The first width of the first molding layer ML1 may be less than the second width of the first molding layer ML1. For example, the sum of the width of the buffer chip 200 and the first width of the first molding layer ML1 on opposing sides of the buffer chip 200 may be equal to the sum of the width of a core chip 300 and the second width of the first molding layer ML1 on opposing sides of the core chip 300. As the width of each of the plurality of core chips 300 is less than the width of the buffer chip 200, the first width of the first molding layer ML1 may be less than the second width of the first molding layer ML1. In some embodiments, the sum of the width of the buffer chip 200 and the first width of the first molding layer ML1 on opposing sides of the buffer chip 200 may be equal to the width of the passivation layer 100.

The first molding layer ML1 may include an epoxy resin, a polyimide resin, or the like. The first molding layer ML1 may include, for example, an epoxy molding compound (EMC).

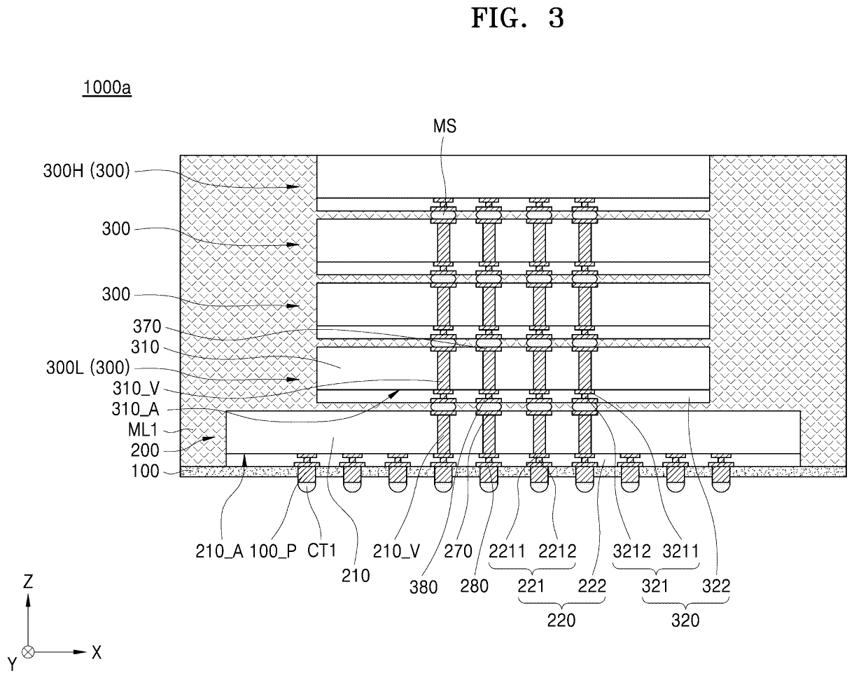

FIG. 3 is a schematic cross-sectional view of a chip stack structure 1000a according to an embodiment.

Many of the components making up the chip stack structure 1000a to be described below and the materials making up the components may be the same as, substantially the same as, or similar to those described above with reference to FIG. 2. Therefore, for convenience of explanation, differences between the chip stack structure 1000a of FIG. 3 and the chip stack structure 1000 of FIG. 2 described above may be mainly described and description that would be redundant may be omitted.

The chip stack structure 1000a may include a passivation layer 100, a buffer chip 200, a plurality of core chips 300, and a first molding layer ML1.

The width of the passivation layer 100 may be greater than the width of the buffer chip 200. The width of the buffer chip 200 may be greater than the width of each of the plurality of core chips 300. The first molding layer ML1 may be in contact with the upper surface of the passivation layer 100 and may be in contact with the side surfaces of the buffer chip 200 and the side surfaces of each of the plurality of core chips 300. The buffer chip 200 may be embedded in the first molding layer ML1. For example, the outer surface of the buffer chip 200 may not be exposed to the outside of the chip stack structure 1000a.

A plurality of conductive pillars 100_P may pass through the passivation layer 100. The plurality of conductive pillars 100_P may be located below the buffer chip 200. For example, the plurality of conductive pillars 100_P may be located only in a portion of the passivation layer 100 that overlaps vertically with the buffer chip 200 and may not be located in a portion of the passivation layer 100 that does not overlap vertically with the buffer chip 200.

The lower surface of the buffer chip 200 may be in contact with the passivation layer 100. For example, a plurality of first lower pads 280 of the buffer chip 200 may be respectively in contact with the plurality of conductive pillars 100_P.

The buffer chip 200 may be electrically connected to a bottom core chip 300L through a plurality of connection terminals MS. For example, the plurality of connection terminals MS may be located between a plurality of first upper pads 270 of the buffer chip 200 and a plurality of second lower pads 380 of the bottom core chip 300L. In some embodiments, an underfill layer may be located between the buffer chip 200 and the bottom core chip 300L, which are spaced apart from each other by the plurality of connection terminals MS.

The plurality of core chips 300 may be electrically connected to each other through corresponding connection terminals MS of the plurality of connection terminals MS. For example, the corresponding connection terminals MS of the plurality of connection terminals MS may be located between adjacent core chips 300 among the plurality of core chips 300. For example, the corresponding connection terminals MS of the plurality of connection terminals MS may be located between the plurality of second lower pads 380 of the upper core chip 300 among the adjacent core chips 300 and the plurality of second upper pads 370 of the lower core chip 300 among the adjacent core chips 300. In some embodiments, the underfill layer may be located between the plurality of core chips 300 spaced apart from each other by the corresponding connection terminals MS of the plurality of connection terminals MS.

The corresponding connection terminals MS of the plurality of connection terminals MS located between the buffer chip 200 and the bottom core chip 300L and the corresponding connection terminals MS of the plurality of connection terminals MS located between the plurality of core chips 300 may be formed from, for example, solder balls or solder bumps.

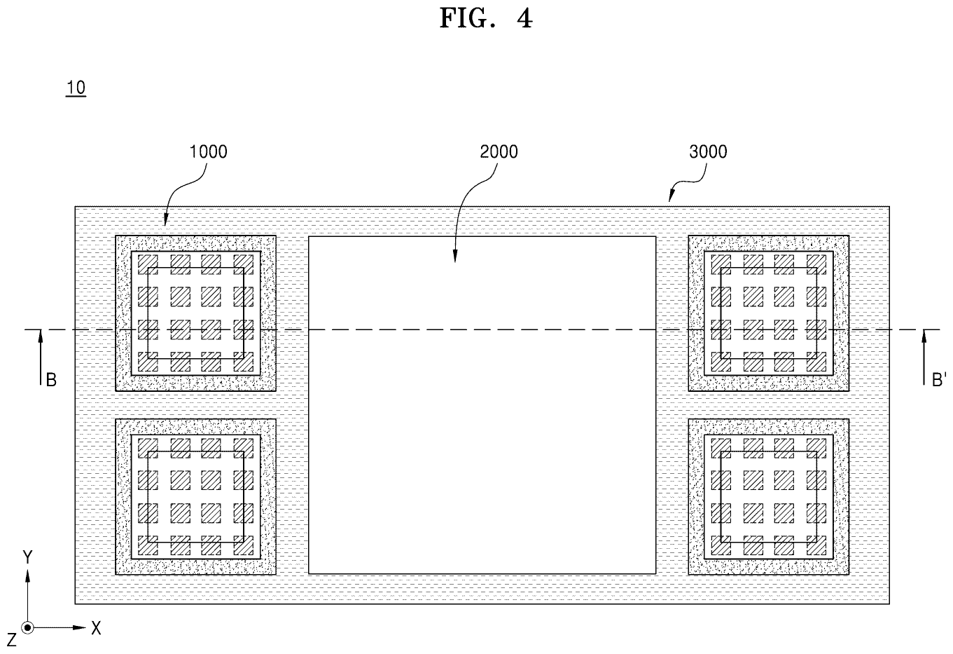

FIG. 4 is a schematic plan view of a semiconductor package 10 according to an embodiment. FIG. 5 is a schematic cross-sectional view of the semiconductor package 10 of FIG. 4 taken along line B-B′ in FIG. 4.

Referring to FIGS. 4 and 5, the semiconductor package 10 may include a package substrate 3000, a chip stack structure 1000, a semiconductor chip 2000, and a second molding layer ML2. In FIG. 4, the semiconductor package 10 is shown to include one semiconductor chip 2000 and four chip stack structures 1000, but the number of semiconductor chips 2000 and chip stack structures 1000, included in the semiconductor package 10, is not limited thereto.

The package substrate 3000 may include an interposer including a substrate 400 and a through via 400_V passing through the substrate 400. For example, the package substrate 3000 may include a glass interposer in which the substrate 400 includes glass and the through via 400_V includes a through glass via (TGV). However, the inventive concept is not limited thereto. The package substrate 3000 may include a silicon interposer in which the substrate 400 includes Si and the through via 4000_V includes a through silicon via (TSV).

In some embodiments, the package substrate 3000 may include a printed circuit board (PCB) including a core insulating layer including at least one material selected from phenolic resin, epoxy resin, and polyimide.

In some embodiments, the package substrate 3000 may further include an upper package pad 401 located on the upper surface of the substrate 400 and a lower package pad 402 located on the lower surface of the substrate 400. The upper package pad 401 may be electrically connected to the lower package pad 402 by the through via 400_V or internal wires. The internal wires of the package substrate 3000 may be configured to transmit/receive electrical signals between the chip stack structure 1000 and the semiconductor chip 2000 mounted on the package substrate 3000. For example, each of the upper package pad 401 and the lower package pad 402 may include copper, nickel, stainless steel, or beryllium copper.

In some embodiments, the package connection terminals CT may be respectively attached to the lower package pads 402 of the package substrate 3000. The package connection terminals CT may be configured to electrically and physically connect the package substrate 3000 to an external device on which the package substrate 3000 is mounted. The package connection terminals CT may be formed, for example, from solder balls or solder bumps.

The semiconductor chip 2000 may be located on the package substrate 3000. The semiconductor chip 2000 may include an active surface and an inactive surface on an opposite side of the active surface. In some embodiments, the semiconductor chip 2000 may include an application specific integrated circuit (ASIC).

In some embodiments, the semiconductor chip 2000 may be mounted on the package substrate 3000 such that the active surface of the semiconductor chip 2000 faces the package substrate 3000. For example, the semiconductor chip 2000 may be disposed on the package substrate 3000 in a face-down manner.

In some embodiments, various types of individual devices may be located on the active surface of the semiconductor chip 2000. For example, the individual devices may include various microelectronic devices, for example, a CMOS transistor, MOSFET, an image sensor, such as LSI and a CIS, a MEMS, an active device, and a passive device.

In some embodiments, the semiconductor chip 2000 may further include a chip lower pad 2001 formed on a lower surface of the semiconductor chip 2000. For example, the chip lower pad 2001 of the semiconductor chip 2000 may be electrically connected to a wiring structure formed on the active surface of the semiconductor chip 2000.

The semiconductor chip 2000 and the package substrate 3000 may be electrically connected to each other by external connection terminals CT2 located between the chip lower pad 2001 of the semiconductor chip 2000 and the upper package pad 401 of the package substrate 3000. However, the inventive concept is not limited thereto. The semiconductor chip 2000 and the package substrate 3000 may be electrically connected to each other by an ACF, direct bonding, or hybrid bonding.

The chip stack structure 1000 may be located on the package substrate 3000. The chip stack structure 1000 may be spaced apart from the semiconductor chip 2000 in the horizontal direction. A plurality of chip stack structures 1000 may be located on the package substrate 3000. For example, the chip stack structures 1000 may surround the semiconductor chip 2000. For example, the chip stack structures 1000 may be arranged on both sides of the semiconductor chip 2000. The chip stack structures 1000 may be electrically connected to the semiconductor chip 2000 through the package substrate 3000.

The chip stack structure 1000 may include a passivation layer 100, a plurality of conductive pillars 100_P, a buffer chip 200, a plurality of core chips 300, and a first molding layer ML1. For example, the chip stack structure 1000 of FIG. 5 may be the same as or substantially the same as the chip stack structures (1000 of FIGS. 2 and 1000a of FIG. 3) described above.

The passivation layer 100 may be located at the bottom of the chip stack structure 1000. The passivation layer 100 may be located below the buffer chip 200 so as to protect the buffer chip 200 from the outside. In particular, the passivation layer 100 may protect the plurality of first lower pads 280 (see FIG. 2) of the buffer chip 200 from the outside. In some embodiments, the passivation layer 100 may have a single continuous homogenous layer structure and the thickness of the passivation layer 100 may be about 3μm to about 7μm.

The buffer chip 200 may be located on the upper surface of the passivation layer 100. The buffer chip 200 may be located on the upper surface of the passivation layer 100 in a face-down manner. The width of the buffer chip 200 may be less than the width of the passivation layer 100. The side surfaces of the buffer chip 200 may overlap with the upper surface of the passivation layer 100 in the vertical direction (Z direction).

The plurality of conductive pillars 100_P may pass through the passivation layer 100. The upper surface of each of the plurality of conductive pillars 100_P may be in contact with the lower surface of each of the plurality of first lower pads 280 (see FIG. 2) of the buffer chip 200. Each of the plurality of conductive pillars 100_P may include a portion protruding out of the passivation layer 100. For example, the lower surface of each of the plurality of conductive pillars 100_P may be located outside the passivation layer 100. The lower surface of each of the plurality of conductive pillars 100_P and the lower surface of the passivation layer 100 may not be coplanar.

In some embodiments, the plurality of conductive pillars 100_P may be located below the buffer chip 200. For example, the plurality of conductive pillars 100_P may pass through a portion of the passivation layer 100 that overlaps with the buffer chip 200 in the vertical direction (Z direction). For example, the plurality of conductive pillars 100_P may not be located in a portion of the passivation layer 100 that is in contact with the first molding layer ML1.

The plurality of conductive pillars 100_P may be electrically connected to the upper package pad 401 of the package substrate 3000 by the external connection terminals CT1 located between the plurality of conductive pillars 100_P and the upper package pad 401 of the package substrate 3000. For example, the buffer chip 200 and the plurality of core chips 300 of the chip stack structure 1000 may be electrically connected to the package substrate 3000 through the external connection terminals CT1.

The plurality of core chips 300 may be stacked on the buffer chip 200. The widths of the plurality of core chips 300 may be equal to each other. The width of each of the plurality of core chips 300 may be less than the width of the buffer chip 200. The side surfaces of each of the plurality of core chips 300 may overlap with the upper surface of the buffer chip 200 in the vertical direction (Z direction).

In some embodiments, the buffer chip 200 may include a buffer chip including a serial-parallel conversion circuit and a controller for controlling the plurality of core chips 300, wherein each of the plurality of core chips 300 may include a memory chip including memory cells. For example, the chip stack structure 1000 including the buffer chip 200 and the plurality of core chips 300 may include HBM, the buffer chip 200 may be referred to as an HBM controller die, and each of the plurality of core chips 300 may be referred to a DRAM die.

The first molding layer ML1 may be located above the passivation layer 100 and may be in contact with the side surfaces of the buffer chip 200 and the side surfaces of each of the plurality of core chips 300. The first molding layer ML1 may adhere to the upper surface of the passivation layer 100. For example, the side surfaces of the first molding layer ML1 may be aligned with the side surfaces of the passivation layer 100 in the vertical direction (Z direction). The buffer chip 200 may be embedded in the first molding layer ML1. The buffer chip 200 may not be exposed to the outside. The upper surface of the top core chip 300H and the upper surface of the first molding layer ML1 may be coplanar.

The width between the outer surface and the inner surface of the first molding layer ML1 in a portion where the first molding layer ML1 is in contact with the side surfaces of the buffer chip 200 may be less than the width between the outer surface and the inner surface of the first molding layer ML1 in a portion where the first molding layer ML1 is in contact with the side surfaces of the plurality of core chips 300.

The second molding layer ML2 may be located on the package substrate 3000 and may surround the chip stack structure 1000 and the semiconductor chip 2000. For example, the second molding layer ML2 may protect the chip stack structure 1000 and the semiconductor chip 2000 from the external environment. The upper surface of the second molding layer ML2 may be the same as or substantially the same as the upper surface of the chip stack structure 1000 and the upper surface of the semiconductor chip 2000.

In some embodiments, the second molding layer ML2 may include an epoxy resin, a polyimide resin, or the like. The first molding layer ML1 may include, for example, an EMC.

In some embodiments, there may be an interface (e.g., a change in structure or discontinuity) between the second molding layer ML2 and the first molding layer ML1 of the chip stack structure 1000. For example, although the constituent materials of the first molding layer ML1 and the second molding layer ML2 may be the same, the curing timing of the first molding layer ML1 may be different from that of the second molding layer ML2 so that there may be an interface (e.g., a change in structure or discontinuity) between the first molding layer ML1 and those of the second molding layer ML2.

FIGS. 6A to 6I are diagrams illustrating a method of manufacturing a chip stack structure 1000 according to a process sequence, according to an embodiment. FIGS. 6A to 6I are diagrams schematically illustrating a process of manufacturing the chip stack structure 1000 including a passivation layer 100 including an oxide.

Referring to FIGS. 6A to 6I, the method of manufacturing the chip stack structure 1000 may include: forming the passivation layer 100 on a first carrier substrate CR1; mounting a buffer chip 200 on the passivation layer 100; mounting a plurality of core chips 300 on the buffer chip 200; forming a first molding layer ML1 on the passivation layer 100 to surround the buffer chip 200 and the plurality of core chips 300; and forming a plurality of conductive pillars 100_P to pass through the passivation layer 100.

Referring to FIG. 6A, the passivation layer 100 may be formed on an upper surface of the first carrier substrate CR1. The passivation layer 100 may include an oxide. For example, the passivation layer 100 may be conformally formed on the upper surface of the first carrier substrate CR1. For example, the passivation layer 100 may have a single continuous homogenous layer structure. For example, an alignment mark may be located inside the passivation layer 100. For example, the passivation layer 100 may be used when mounting the buffer chip 200 on the first carrier substrate CR1. In addition, the alignment mark of the passivation layer 100 may be used to align the buffer chip 200 with the first carrier substrate CR1.

Referring to FIG. 6B, the buffer chip 200 may be mounted on the passivation layer 100. For example, the buffer chip 200 may be mounted on the passivation layer 100 such that a first wiring structure 220 of the buffer chip 200 faces the passivation layer 100. For example, the plurality of buffer chips 200 may be mounted on one first carrier substrate CR1 so as to be spaced from each other in the horizontal direction.

Referring to FIG. 6C, a plurality of core chips 300 may be mounted on the buffer chip 200. For example, the width of each of the plurality of core chips 300 may be less than the width of the buffer chip 200. The side surfaces of the plurality of core chips 300 may overlap with the upper surface of the buffer chip 200 in the vertical direction (Z direction). For example, the plurality of core chips 300 may be electrically connected to the plurality of first through electrodes 210_V of the buffer chip 200. In some embodiments, the plurality of second lower pads 380 of the bottom core chip 300L may be diffusion bonded to respective ones of the plurality of first upper pads 270 of the buffer chip 200 to form one body, respectively. For example, the plurality of core chips 300 may be bonded to the buffer chip 200 through hybrid bonding between the plurality of core chips 300 and between the bottom core chip 300L and the buffer chip 200.

In some embodiments, in the process of mounting the buffer chip 200 and the plurality of core chips 300 on the passivation layer 100, warpage of the buffer chip 200 and the plurality of core chips 300 may occur. For example, the warpage of the buffer chip 200 and the plurality of core chips 300 may occur due to a difference in a coefficient of thermal expansion between the upper surface of the buffer chip 200 and the lower surface of each of the plurality of core chips 300 or warpage in an individual chip may occur do to a difference in the coefficient of thermal expansion between an upper surface of the chip and the lower surface of the chip. The passivation layer 100 including an oxide may be pre-designed to compensate for the direction and the degree of warpage. Accordingly, the warpage of the passivation layer 100 may occur in a direction opposite to the direction in which each of the plurality of core chips 300 and the buffer chip 200 warp, to offset the warpage of the buffer chip 200 and the plurality of core chips 300. Accordingly, the quality of the overall chip stack structure 1000 may be improved.

Referring to FIG. 6D, the first molding layer ML1 may be formed to cover the plurality of core chips 300 and the buffer chip 200 on the passivation layer 100. The first molding layer ML1 may be in contact with the side surfaces of the buffer chip 200 and the side surfaces of each of the plurality of core chips 300. The first molding layer ML1 may be in contact with the upper surface of the passivation layer 100.

Thereafter, part of the first molding layer ML1 may be removed to expose the upper surface of the top core chip 300H. Thus, the upper surface of the first molding layer ML1 and the upper surface of the top core chip 300H may be coplanar.

Referring to FIGS. 6E and 6F, the result of FIG. 6D may be transferred to a second carrier substrate CR2. For example, the second carrier substrate CR2 including a release layer RL may be attached to the upper surface of the result of FIG. 6D. After attaching the second carrier substrate CR2 to the first molding layer ML1, the first carrier substrate CR1 may be removed.

For example, the passivation layer 100 may be separated from the first carrier substrate CR1 while the passivation layer 100 remains below the buffer chip 200 and the first molding layer ML1. For example, in the process of removing the first carrier substrate CR1, the result of FIG. 6E may be flipped such that the passivation layer 100 is located at the top and the second carrier substrate CR2 is located at the bottom.

Referring to FIGS. 6G and 6H, the plurality of conductive pillars 100_P passing through the passivation layer 100 may be formed. External connection terminals CT1 may then be respectively attached to the plurality of conductive pillars 100_P. In some embodiments, the external connection terminals CT1 may be respectively attached to the plurality of conductive pillars 100_P after cutting the passivation layer 100 and the first molding layer ML1.

A plurality of trenches TR extending from the upper surface to the lower surface of the passivation layer 100 may be formed. The plurality of trenches TR may be located above the buffer chip 200. For example, the plurality of trenches TR may be located above the plurality of first lower pads 280 of the buffer chip 200. The plurality of first lower pads 280 of the buffer chip 200 may be exposed to the outside through the plurality of trenches TR.

For example, the plurality of trenches TR may be formed in a portion of the passivation layer 100 which is in contact with the buffer chip 200 and may not be formed in a portion of the passivation layer 100 which is in contact with the first molding layer ML1.

Thereafter, the interior of the plurality of trenches TR may be filled with a conductive material to form the plurality of conductive pillars 100_P. For example, an electrolytic plating process may be used to fill the plurality of trenches TR with the conductive material. In some embodiments, in the process of forming the plurality of conductive pillars 100_P, the plurality of conductive pillars 100_P may protrude out of the passivation layer 100. For example, as the thickness of the plurality of conductive pillars 100_P is greater than the height of the plurality of trenches TR, the plurality of conductive pillars 100_P may protrude out of the passivation layer 100. For example, the upper surfaces of the plurality of conductive pillars 100_P and the upper surface of the passivation layer 100 may not be coplanar.

In some embodiments, the width of each of the plurality of trenches TR, on which the plurality of conductive pillars 100_P are formed, may be greater than the width of each of the plurality of conductive pillars 100_P. Accordingly, a portion of each of the plurality of first lower pads 280 of the buffer chip 200 may be exposed to the outside through the plurality of trenches TR.

Referring to FIG. 6I, the result of FIG. 6H may be cut into a plurality of chip stack structures 1000. The result of FIG. 6H may be cut such that the width of the passivation layer 100 is greater than the width of the buffer chip 200. For example, the result of FIG. 6H may be cut such that the first molding layer ML1 remains on the side of the buffer chip 200. For example, the buffer chip 200 may be located inside the first molding layer ML1 and may not be exposed to the outside. For example, the side surfaces of the passivation layer 100 may be aligned with the side surfaces of the first molding layer ML1 in the vertical direction (Z direction).

FIGS. 7A to 7J are diagrams illustrating a method of manufacturing a chip stack structure according to a process sequence, according to an embodiment. FIGS. 7A to 7J are diagrams schematically illustrating the manufacturing process of a chip stack structure 1000b including a passivation layer 100a including PSPI.

Referring to FIGS. 7A to 7J, a method of manufacturing the chip stack structure 1000b may include: forming an oxide layer Ox on a first carrier substrate CR1; mounting a buffer chip 200 on the oxide layer Ox; mounting a plurality of core chips 300 on the buffer chip 200; forming a first molding layer ML1 on the oxide layer Ox to surround the buffer chip 200 and the plurality of core chips 300; removing the oxide layer Ox and forming the passivation layer 100a; and forming a plurality of conductive pillars 100a_P passing through the passivation layer 100a.

The method of manufacturing the chip stack structure 1000b to be described below is the same as, substantially the same as, or similar to that described above with reference to FIGS. 6A to 6I. Therefore, for convenience of explanation, differences between the method of manufacturing the chip stack structure 1000b of FIGS. 7A to 7B and the method of manufacturing the chip stack structure 1000 of FIGS. 6A to 6I described above may be mainly described and descriptions that would be redundant may be omitted.

The oxide layer Ox of FIG. 7A may be the same as or substantially the same as the passivation layer 100a of FIG. 6A. However, the method of manufacturing the chip stack structure 1000 of FIGS. 6A to 6I illustrates an embodiment in which an oxide layer formed on the first carrier substrate CR1 and utilized for bonding of the buffer chip 200 is used as the passivation layer 100a, and the method of manufacturing the chip stack structure 1000b of FIGS. 7A to 7J illustrates an embodiment in which an oxide layer Ox utilized for bonding of the buffer chip 200 is removed and the passivation layer 100a including PSPI is formed.

Referring to FIG. 7A, the oxide layer Ox may be formed on the upper surface of the first carrier substrate CR1. The oxide layer Ox may include an oxide. For example, the oxide layer Ox may be conformally formed on the upper surface of the first carrier substrate CR1. For example, an alignment mark may be located inside the oxide layer Ox. In addition, the alignment mark of the oxide layer Ox may be used to align the buffer chip 200 with the first carrier substrate CR1.

Referring to FIG. 7B, the buffer chip 200 may be mounted on the oxide layer Ox. For example, the buffer chip 200 may be mounted on the oxide layer Ox such that the first wiring structure 220 of the buffer chip 200 faces the oxide layer Ox. For example, the plurality of buffer chips 200 may be mounted on one first carrier substrate CR1 so as to be spaced apart from each other in the horizontal direction.

Referring to FIG. 7C, a plurality of core chips 300 may be mounted on the buffer chip 200. For example, the width of each of the plurality of core chips 300 may be less than the width of the buffer chip 200. The side surfaces of the plurality of core chips 300 may overlap with the upper surface of the buffer chip 200 in the vertical direction (Z direction). For example, the plurality of core chips 300 may be electrically connected to the plurality of first through electrodes 210_V of the buffer chip 200.

In some embodiments, the plurality of second lower pads 380 of the bottom core chip 300L may be respectively diffusion bonded to the plurality of first upper pads 270 of the buffer chip 200 to form one body for each second lower pad 380. For example, the plurality of core chips 300 may be bonded to the buffer chip 200 through hybrid bonding between the plurality of core chips 300 and between the bottom core chip 300L and the buffer chip 200.

Referring to FIG. 7D, the first molding layer ML1 may be formed on the oxide layer Ox to cover the plurality of core chips 300 and the buffer chip 200. The first molding layer ML1 may be in contact with the side surfaces of the buffer chip 200 and the side surfaces of each of the plurality of core chips 300. The first molding layer ML1 may be in contact with the upper surface of the oxide layer Ox.

A portion of the first molding layer ML1 may then be removed to expose the upper surface of the top buffer chip 200. Accordingly, the upper surface of the first molding layer ML1 and the upper surface of the top buffer chip 200 may be coplanar.

Referring to FIGS. 7E and 7F, the result of FIG. 7D may be transferred to the second carrier substrate CR2. For example, the second carrier substrate CR2 including a release layer RL may be attached to the upper surface of the result of FIG. 7D. After attaching the second carrier substrate CR2 to the first molding layer ML1, the first carrier substrate CR1 may be removed.

For example, the oxide layer Ox may be separated from the first carrier substrate CR1 when the oxide layer Ox remains below the buffer chip 200 and the first molding layer ML1. However, the inventive concept is not limited thereto. The oxide layer Ox may be removed together with the first carrier substrate CR1.

For example, in the process of removing the first carrier substrate CR1, the result of FIG. 7E may be flipped such that the oxide layer Ox is located at the top and the second carrier substrate CR2 is located at the bottom.

Referring to FIG. 7G and FIG. 7I, the oxide layer Ox may be removed, and the passivation layer 100a may be formed on the buffer chip 200 and the first molding layer ML1. The plurality of conductive pillars 100a_P passing through the passivation layer 100a may then be formed.

After exposing the first molding layer ML1 and the first wiring structure 220 of the buffer chip 200 to the outside by removing the oxide layer Ox, the passivation layer 100a may be conformally formed on the exposed first molding layer ML1 and buffer chip 200. The passivation layer 100a may include PSPI.

A plurality of trenches TR extending from the upper surface to the lower surface of the passivation layer 100a may be formed. The plurality of trenches TR may be located above the buffer chip 200. For example, the plurality of trenches TR may be located above the plurality of first lower pads 280 of the buffer chip 200. The plurality of first lower pads 280 of the buffer chip 200 may be exposed to the outside through the plurality of trenches TR.

For example, the plurality of trenches TR may be formed in a portion of the passivation layer 100a which is in contact with the buffer chip 200 and may not be formed in a portion of the passivation layer 100a which is in contact with the first molding layer ML1.

Thereafter, the interior of the plurality of trenches TR may be filled with a conductive material to form the plurality of conductive pillars 100a_P. For example, an electrolytic plating process may be used to fill the plurality of trenches TR with the conductive material. In some embodiments, in the process of forming the plurality of conductive pillars 100a_P, the plurality of conductive pillars 100a_P may protrude out of the passivation layer 100a. For example, as the thickness of each of the plurality of conductive pillars 100a_P is greater than the height of each of the plurality of trenches TR, the plurality of conductive pillars 100a_ P may protrude out of the passivation layer 100a. For example, the upper surfaces of the plurality of conductive pillars 100a_P and the upper surface of the passivation layer 100a may not be coplanar.

In some embodiments, the width of each of the plurality of trenches TR, on which the plurality of conductive pillars 100a_P are formed, may be greater than the width of each of the plurality of conductive pillars 100a_ P. Accordingly, a portion of each of the plurality of first lower pads 280 of the buffer chip 200 may be exposed to the outside through the plurality of trenches TR.

In some embodiments, external connection terminals CT1 may be attached on the plurality of conductive pillars 100a_P. In some embodiments, the external connection terminals CT1 may be attached to the plurality of conductive pillars 100a_P after cutting the passivation layer 100a and the first molding layer ML1.

Referring to FIG. 7J, the result of FIG. 7I may be cut to a plurality of chip stack structures 1000b. The result of FIG. 7I may be cut such that the width of the passivation layer 100a is greater than the width of the buffer chip 200. For example, the result of FIG. 7I may be cut such that the first molding layer ML1 remains on the side of the buffer chip 200. For example, the buffer chip 200 may be located inside the first molding layer ML1 and may not be exposed to the outside. For example, the side surfaces of the passivation layer 100a may be aligned with the side surfaces of the first molding layer ML1 in the vertical direction (Z direction).

While the inventive concept has been particularly shown and described with reference to embodiments thereof, it will be understood that various changes in form and details may be made therein without departing from the spirit and scope of the following claims.

What is claimed is:

1. A chip stack structure, comprising:
a passivation layer;
a plurality of conductive pillars passing through the passivation layer;
a buffer chip located on the passivation layer;
a plurality of core chips located on the buffer chip and stacked in a vertical direction; and
a first molding layer located on the passivation layer and surrounding the buffer chip and the plurality of core chips,
wherein an area of an upper surface of the passivation layer is greater than an area of a lower surface of the buffer chip.

2. The chip stack structure of claim 1, wherein side surfaces of the buffer chip overlap with the upper surface of the passivation layer in the vertical direction.

3. The chip stack structure of claim 1, wherein
an area of a lower surface of each of the plurality of core chips is less than an area of an upper surface of the buffer chip, and
side surfaces of each of the plurality of core chips overlap with the upper surface of the buffer chip in the vertical direction.

4. The chip stack structure of claim 1, wherein
the passivation layer is divided into a center region and an edge region surrounding the center region,
the upper surface of the passivation layer is in contact with the buffer chip in the center region of the passivation layer, and
the upper surface of the passivation layer is in contact with the first molding layer in the edge region of the passivation layer.

5. The chip stack structure of claim 4, wherein the plurality of conductive pillars are located within the center region of the passivation layer.

6. The chip stack structure of claim 1, wherein the plurality of conductive pillars are located below the buffer chip and are electrically connected to the buffer chip.

7. The chip stack structure of claim 6,
wherein the buffer chip comprises a plurality of first lower pads, and
wherein the plurality of conductive pillars overlap with the plurality of first lower pads of the buffer chip, respectively, in the vertical direction.

8. The chip stack structure of claim 1, wherein the passivation layer has a single continuous homogenous layer structure.

9. The chip stack structure of claim 1, wherein each of the plurality of conductive pillars comprises a portion protruding outward from a lower surface of the passivation layer.

10. The chip stack structure of claim 1, wherein
the buffer chip comprises a first substrate having an active surface and an inactive surface on an opposite side of the first substrate, and a first wiring structure located on the active surface of the first substrate, and
a first wiring insulating layer of the first wiring structure is in contact with and is covalently bonded to the passivation layer.

11. The chip stack structure of claim 1, wherein the passivation layer is an oxide.

12. The chip stack structure of claim 1, wherein a thickness of the passivation layer in the vertical direction is about 3 μm to about 7 μm.

13. A chip stack structure, comprising:
a passivation layer;
a buffer chip located on the passivation layer and comprising a plurality of first lower pads;
a plurality of core chips located on the buffer chip and stacked in a vertical direction; and
a first molding layer located on an upper surface of the passivation layer and contacting side surfaces of the buffer chip and side surfaces of each of the plurality of core chips,
wherein an area of the upper surface of the passivation layer is greater than an area of a lower surface of the buffer chip,
wherein an area of an upper surface of the buffer chip is greater than an area of a lower surface of each of the plurality of core chips, and
wherein side surfaces of the passivation layer are aligned with side surfaces of the first molding layer in the vertical direction.

14. The chip stack structure of claim 13, wherein
the first molding layer is divided into a lower region and an upper region,
the lower region of the first molding layer is in contact with the upper surface of the passivation layer and side surfaces of the buffer chip, and
the upper region of the first molding layer is in contact with the upper surface of the buffer chip and the side surfaces of each of the plurality of core chips.

15. The chip stack structure of claim 14, wherein, when a distance between a side surface of the first molding layer exposed to the outside and a side surface of the first molding layer in contact with the buffer chip, among the side surfaces of the first molding layer, is a first width in the lower region of the first molding layer and a distance between a side surface of the first molding layer exposed to the outside and a side surface of the first molding layer in contact with the plurality of core chips, among the side surfaces of the first molding layer, is a second width in the upper region of the first molding layer, wherein the first width is less than the second width.

16. The chip stack structure of claim 13, wherein an upper surface of the first molding layer is coplanar with an upper surface of the core chip located at the top of the plurality of core chips.

17. The chip stack structure of claim 13, wherein
the passivation layer further comprises a plurality of conductive pillars, and
the plurality of conductive pillars are located on lower surfaces of the plurality of first lower pads of the buffer chip, respectively.

18. A semiconductor package comprising:
a package substrate;
a chip stack structure located on the package substrate;
a semiconductor chip located on the package substrate and spaced apart from the chip stack structure in a horizontal direction; and
a second molding layer located on the package substrate and surrounding the chip stack structure and the semiconductor chip,
wherein the chip stack structure comprises:
a passivation layer on the package substrate;
a plurality of conductive pillars passing through the passivation layer and electrically connected to the package substrate;
a buffer chip located on the passivation layer and electrically connected to the plurality of conductive pillars;
a plurality of core chips located on the buffer chip and stacked in a vertical direction; and
a first molding layer located on the passivation layer and surrounding the buffer chip and the plurality of core chips, and
wherein an area of an upper surface of the passivation layer is greater than an area of a lower surface of the buffer chip.

19. The semiconductor package of claim 18, wherein the buffer chip of the chip stack structure is spaced apart from the second molding layer with the first molding layer of the chip stack structure positioned therebetween.

20. The semiconductor package of claim 18, wherein
the passivation layer of the chip stack structure has a single continuous homogenous layer structure,
the upper surface of the passivation layer of the chip stack structure is divided into a center region and an edge region surrounding the center region,
the center region of the upper surface of the passivation layer of the chip stack structure is in contact with the buffer chip of the chip stack structure,
the edge region of the upper surface of the passivation layer of the chip stack structure is in contact with the first molding layer of the chip stack structure, and
an upper surface of each of the plurality of conductive pillars of the chip stack structure is located within the center region of the upper surface of the passivation layer of the chip stack structure.
